(19) United States
(12) Patent Application Publication
(10) Pub. No.: US 2022/0197280 A1
(43) Pub. Date: Jun. 23, 2022

(54) Systems and Methods for Error Sourcing in Autonomous Vehicle Simulation

(71) Applicant: UATC, LLC, San Francesco, CA (US)

(72) Inventors: Arun David Kain Venkatadri, Pittsburgh, PA (US); Jason C. Lee, Pittsburgh, PA (US); Yilun Tang, Pittsburgh, PA (US)

(21) Appl. No.: 17/140,606

(22) Filed: Jan. 4, 2021

Related U.S. Application Data
(60) Provisional application No. 63/129,173, filed on Dec. 22, 2020.

(51) Int. Cl. G05D 1/00; G06F 30/20; G07C 5/08; B60W 50/00

(52) U.S. Cl. CPC G05D 1/0088; G06F 30/20; B60W 2050/0083; B60W 50/00; G07C 5/0808

(57) ABSTRACT

Systems and methods of the present disclosure are directed to a computer-implemented method. The method can include obtaining a first plurality of testing parameters for an autonomous vehicle testing scenario associated with a plurality of performance metrics based at least in part on a first sampling rule. The method can include simulating the autonomous vehicle testing scenario using the first plurality of testing parameters to obtain a first scenario output. The method can include evaluating an optimization function that evaluates the first scenario output to obtain simulation error data that corresponds to a performance metric. The method can include determining a second sampling rule associated with the performance metric. The method can include obtaining a second plurality of testing parameters for the autonomous vehicle testing scenario based at least in part on the second sampling rule.

### RELATED APPLICATION

The present application is based on and claims benefit of U.S. Provisional Patent Application No. 63/129,173 having a filing date of Dec. 22, 2020, which is incorporated by reference herein.

### FIELD

The present disclosure relates generally to vehicle services and, more particularly, simulation of autonomous vehicle systems.

### BACKGROUND

An autonomous vehicle can be capable of sensing its environment and navigating without human input. In particular, an autonomous vehicle can observe its surrounding environment using a variety of sensors and can attempt to comprehend the environment by performing various processing techniques on data collected by the sensors. Given knowledge of its surrounding environment, the autonomous vehicle can identify an appropriate motion path for navigating through such a surrounding environment.

### SUMMARY

Aspects and advantages of embodiments of the present disclosure will be set forth in part in the following description, or may be learned from the description, or may be learned through practice of the embodiments.

One example aspect of the present disclosure is directed to a computer-implemented method. The method can include obtaining, by a computing system comprising one or more computing devices, a first plurality of testing parameters for an autonomous vehicle testing scenario based at least in part on a first sampling rule, wherein the autonomous vehicle testing scenario is associated with a plurality of performance metrics. The method can include simulating, by the computing system, the autonomous vehicle testing scenario using the first plurality of testing parameters to obtain a first scenario output. The method can include evaluating, by the computing system, an optimization function that evaluates the first scenario output to obtain simulation error data that corresponds to a performance metric of the plurality of performance metrics. The method can include determining, by the computing system based at least in part on the simulation error data, a second sampling rule associated with the performance metric. The method can include obtaining, by the computing system, a second plurality of testing parameters for the autonomous vehicle testing scenario based at least in part on the second sampling rule.

Another example aspect of the present disclosure is directed to a computing system. The computing system can include one or more processors. The computing system can include one or more tangible, non-transitory computer readable media storing computer-readable instructions that when executed by the one or more processors cause the one or more processors to perform operations. The operations can include obtaining a first plurality of testing parameters for an autonomous vehicle testing scenario based at least in part on a first sampling rule, wherein the autonomous vehicle testing scenario is associated with plurality of performance metrics. The operations can include simulating the autonomous vehicle testing scenario using the first plurality of testing parameters to obtain a first scenario output. The operations can include evaluating an optimization function that evaluates a difference between the first scenario output and a ground truth label to obtain simulation error data that corresponds to a performance metric of the plurality of performance metrics. The operations can include determining, based at least in part on the simulation error data, a second sampling rule associated with the performance metric. The operations can include obtaining a second plurality of testing parameters for the autonomous vehicle testing scenario based at least in part on the second sampling rule.

Another example aspect of the present disclosure is directed to one or more tangible, non-transitory computer readable media storing computer-readable instructions that when executed by one or more processors cause the one or more processors to perform operations. The operations can include obtaining a first plurality of testing parameters for an autonomous vehicle testing scenario based at least in part on a first sampling rule, wherein the autonomous vehicle testing scenario comprises a plurality of performance metrics, wherein the first sampling rule is associated with a first performance metric. The operations can include simulating the autonomous vehicle testing scenario using the first plurality of testing parameters to obtain a first scenario output. The operations can include evaluating an optimization function that evaluates a difference between the first scenario output and a ground truth label to obtain simulation error data that corresponds to the first performance metric. The operations can include determining, based at least in part on the simulation error data, a second sampling rule associated with a second performance metric of the plurality of performance metrics. The operations can include obtaining a second plurality of testing parameters for the autonomous vehicle testing scenario based at least in part on the second sampling rule.

Other example aspects of the present disclosure are directed to other systems, methods, vehicles, apparatuses, tangible non-transitory computer-readable media, and the like for error sourcing in autonomous vehicle simulation.

The autonomous vehicle technology described herein can help improve the safety of passengers of an autonomous vehicle, improve the safety of the surroundings of the autonomous vehicle, improve the experience of the rider and/or operator of the autonomous vehicle, as well as provide other improvements as described herein. Moreover, the autonomous vehicle technology of the present disclosure can help improve the ability of an autonomous vehicle to effectively provide vehicle services to others and support the various members of the community in which the autonomous vehicle is operating, including persons with reduced mobility and/or persons that are underserved by other transportation options. Additionally, the autonomous vehicle of the present disclosure may reduce traffic congestion in communities as well as provide alternate forms of transportation that may provide environmental benefits.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a block diagram of an example autonomous vehicle computing system according to example embodiments of the present disclosure;

FIG. 2 depicts an example service infrastructure system according to example embodiments of the present disclosure;

FIG. 3 depicts an example data flow diagram for determination of a second sampling rule using an optimization function according to example embodiments of the present disclosure;

FIG. 4 depicts an example of testing scenario parameter data according to example embodiments of the present disclosure;

FIG. 5 depicts an example of performance metric data according to example embodiments of the present disclosure;

FIG. 6 depicts a data flow diagram for simulation of an autonomous vehicle testing scenario using a sampled plurality of testing parameters according to example embodiments of the present disclosure;

FIG. 7 depicts a flowchart of a method for obtaining sampled parameters according to a sampling rule determined using an optimization function according to example embodiments of the present disclosure;

FIG. 8 depicts example system units for performing operations and functions according to example embodiments of the present disclosure; and

FIG. 9 depicts example system components of an example computing system according to example embodiments of the present disclosure.

### DETAILED DESCRIPTION

Example aspects of the present application are directed to sourcing of errors from autonomous vehicle simulation. More particularly, the systems and methods of the present disclosure are directed to evaluation of an optimization function configured to characterize a loss associated with errors found in autonomous vehicle systems simulation. As an example, a first plurality of testing parameters can be obtained for an autonomous vehicle testing scenario based on a first sampling rule (e.g., a rule specifying selection of certain type(s) of parameters, etc.). The autonomous vehicle testing scenario can be associated with a plurality of performance metrics (e.g., a braking efficiency metric, a yield maneuver performance metric, a lane deviation metric, etc.). Using the first plurality of testing parameters, the autonomous vehicle testing scenario can be simulated to obtain a first scenario output (e.g., data descriptive of the performance of the autonomous vehicle for the performance metrics, etc.). An optimization function (e.g., a characterization of error loss, etc.) can be evaluated that evaluates a difference between the first scenario output and a ground truth label (e.g., an ideal performance for the performance metrics, etc.) to obtain simulation error data that corresponds to a performance metric of the plurality of performance metrics. Based at least in part on the optimization function and/or the simulation error data, a second sampling rule can be determined associated with the performance metric. Using the second sampling rule, a second plurality of testing parameters can be obtained for the autonomous vehicle testing scenario.

As an example, a first plurality of testing parameters can be obtained and used to simulate an autonomous vehicle testing scenario (e.g., a scenario in which the vehicle slows to avoid a non-compliant pedestrian, etc.). The optimization function can be evaluated to obtain simulation error data that corresponds to a performance metric that characterizes how the autonomous vehicle performed when completing a braking maneuver. For example, the simulation error data can indicate that the performance of the autonomous vehicle was within a range of error for completion of a braking maneuver. Based on the simulation data, a second sampling rule can be determined that is associated with the performance metric. For example, the second sampling rule can be configured to emphasize the parameters that caused and/or magnified the previous error in completing the braking maneuver (e.g., lowering an amount of time for the autonomous vehicle to complete the braking maneuver, adjusting road surface conditions, adding inclement weather, etc.). A second plurality of testing parameters can be obtained for the autonomous vehicle testing scenario based at least in part on the second sampling rule. In such fashion, an optimization function can be leveraged to generate parameter sampling strategies configured to emphasize the source of error within an autonomous vehicle testing scenario, therefore significantly reducing the number of simulations necessary to identify and correct the error.

More particularly, a first plurality of testing parameters can be obtained for an autonomous vehicle testing scenario. An autonomous vehicle testing scenario can be or otherwise represent a scenario in which an autonomous vehicle can operate. As an example, the autonomous vehicle testing scenario may represent a series of maneuvers that an autonomous vehicle must perform to navigate a specific series of roads. As another example, the autonomous vehicle testing scenario may represent one or more maneuvers in response to action(s) taken by a separate testing entity(s) (e.g., additional vehicle(s), one or more pedestrian(s), a road obstruction, a traffic pattern, etc.). More generally, it should be noted that the autonomous vehicle testing scenario can broadly represent any scenario that the autonomous vehicle could encounter.

The autonomous vehicle testing scenario can include a plurality of performance metrics. A performance metric can be or otherwise indicate a performance value and/or performance threshold necessary for compliance with a certain aspect of the autonomous vehicle testing scenario. As an example, the performance metric may indicate a performance threshold that an autonomous vehicle must achieve for a certain maneuver performed during the autonomous vehicle testing scenario (e.g., entering an intersection, exiting a driveway, exiting a roundabout, etc.). If the performance value of an autonomous vehicle (e.g., a scalar value, a binary value, etc.) for a performance metric does not meet the performance threshold, an error can be detected for that particular performance metric. As another example, a performance threshold for perception of a non-compliant testing entity (e.g., a runaway shopping cart, etc.) may be or otherwise indicate a threshold amount of time to perceive the non-compliant testing entity. As such, the plurality of performance metrics can be utilized to evaluate the performance of, and detect error(s) for, the autonomous vehicle for any perception, prediction, and/or motion planning operations completed during the autonomous vehicle testing scenario.

Additionally, or alternatively, in some implementations, each of the plurality of performance metrics can describe an ideal performance value or a range of ideal performance for a particular aspect of the autonomous vehicle testing scenario. As an example, a performance metric can be or otherwise describe a value (e.g., a scalar value, a binary value, an integer value, etc.) or range of values associated with performance of a certain driving maneuver. The performance of the maneuver during the testing scenario can be evaluated (e.g., using an evaluation module, etc.) to obtain a value representative of how the vehicle performed the maneuver. The representative value and the ideal value (e.g., the performance metric) can be compared, and an error can be detected when performance of the vehicle deviates from the ideal performance by a certain degree. As an example, the performance metric can indicate a range of values from 5 ms to 10 ms that represent an ideal performance for perceiving a moving object. The representative value of performance of the perception operation by the autonomous vehicle can be 25 ms. An error can be detected based on the performance of the autonomous vehicle deviating from the ideal performance described by the performance metric by a certain degree. As another example, the performance metric can indicate a binary value that represents an ideal performance for completely stopping before entering an intersection (e.g., a binary value). The representative value of performance of the complete stop operation by the autonomous vehicle can be 1 (e.g., the vehicle did stop). As the vehicle did not deviate from the ideal performance described by the performance metric, an error would not be detected.

The first plurality of testing parameters can be or otherwise include parameters that specify operating condition(s) for the autonomous vehicle testing scenario. Rather, the first plurality of testing parameters can include any parameter associated with the testing of an autonomous vehicle testing scenario. As an example, the parameters may describe environmental condition(s) for the autonomous vehicle testing scenario (e.g., humidity, sunlight, cloud coverage, weather, temperature, wind, etc.). As another example, the parameters may describe vehicle maneuver(s) required to be performed for the autonomous vehicle testing scenario (e.g., execution of a certain turn maneuver, acceleration, deceleration, reaction to external testing entity(s), motion planning, etc.). As another example, the parameters may describe operational condition(s) for the autonomous vehicle testing scenario (e.g., a speed limit, no-stopping zones, a number of lanes, object(s) included in a road network, lateral clearance, underbody clearance, turn radius, a degree of incline/decline, bike lanes, general road conditions (e.g., surface characteristics, types of lanes, laws of the road, etc.), etc.). As yet another example, the parameters may describe a location, pose, type and/or behavior for each of one or testing entities included in the scenario (e.g., specifying that a testing entity is riding a bicycle and is not compliant with road rules, etc.). For example, the parameters may describe an actor located at the sidewalk of an intersection, and who's behavior includes facing the intersection and walking into the intersection at predetermined time. As such, the parameters included in the first plurality of testing parameters can broadly describe any possible detail or characteristic of the autonomous vehicle testing scenario.

In some implementations, the plurality of parameters can additionally modify or adjust the type of autonomous vehicle testing scenario selected. As an example, a first plurality of testing parameters for an autonomous vehicle testing scenario may describe a scenario in which a vehicle takes a right turn through an intersection. A second plurality of testing parameters for an autonomous vehicle may describe a scenario in which a vehicle navigates a roundabout turn. Additionally, or alternatively, in some implementations, the scenario type can be sampled from within a scenario family or from a separate scenario family.

More particularly, in some implementations, scenarios can be organized within scenario families based on certain shared characteristics or commonalities (e.g., required maneuver(s), required operation(s) (e.g., perception, prediction, etc.), shared environmental characteristic(s) (e.g., adverse weather conditions, night time, day time, etc.), shared performance metric(s) (e.g., perception in response to occlusion, etc.), etc.). As an example, scenarios may be grouped by a common required maneuver (e.g., entering an intersection, etc.). For example, a scenario family may include a first scenario in which a vehicle enters an intersection and performs a right turn maneuver, and a second scenario in which a vehicle enters an intersection and performs a left turn maneuver. As another example, a scenario family may be grouped based on a shared adverse weather condition. For example, a scenario family may include a first scenario in which a vehicle takes a right turn in icy road conditions, and a second scenario in which the vehicle takes a left turn against oncoming traffic in icy road conditions. As such, it should be broadly understood that a plurality of parameters can, in some implementations, describe the scenario itself, and that a sampling rule can additionally indicate whether a scenario should be sampled from within a scenario family or from a separate scenario family.

The first plurality of testing parameters can be obtained based at least in part on a first sampling rule. The first sampling rule can describe or otherwise indicate a certain group of parameters to be sampled from (e.g., selected from, etc.). As an example, a group of parameters can exist for an autonomous vehicle testing scenario. A sampling rule can be configured to indicate a certain type of parameter from the group of parameters that emphasizes one or more particular performance metrics for an autonomous vehicle testing scenario. For example, a first sampling rule can be configured to emphasize an “entering intersection” performance metric for an autonomous vehicle testing scenario. To do so, the first sampling rule can indicate a sampling of parameters that are most likely to cause an error for the “entering intersection” performance metric (e.g., adding a number of actors to the intersection, decreasing compliance for actors in the intersection, adding pedestrian actors to the intersection, reducing visibility, increasing occlusion of the vehicle, increasing adverse weather conditions, etc.). In such fashion, a sampling rule can be or otherwise describe a method of sampling parameters (e.g., for inclusion in the plurality of testing parameters, etc.) that is configured to emphasize a certain aspect of an autonomous vehicle testing scenario.

It should be noted that the generation of a sampling rule (e.g., the first sampling rule, etc.) can be accomplished in a variety of ways. As an example, a user (e.g., a testing engineer, etc.) can design an initial sampling rule that is not configured to emphasize any particular performance metric of the autonomous vehicle testing scenario (e.g., to identify any initial errors in the simulation, etc.). As another example, a computing system can utilize an optimization function (e.g., error loss characterization, etc.) to generate a sampling rule configured to emphasize parameter(s) most associated with a performance metric from a plurality of performance metrics. Additionally, or alternatively, the optimization function itself can be optimized by a user and/or the computing system to characterize the error loss of the simulation more accurately.

Once the first plurality of testing parameters is obtained based on the first sampling rule, the autonomous vehicle testing scenario can be simulated using the first plurality of testing parameters to obtain a first scenario output. It should be noted that the simulation of the autonomous vehicle testing scenario can be accomplished using any type of simulation system(s). The first scenario output can describe an overall pass/fail state for the autonomous vehicle testing scenario. Additionally, in some implementations, the first scenario output can include a plurality of performance values that respectively correspond to the plurality of performance metrics. For example, the first scenario output may include a value (e.g., a scalar value, etc.) indicative of the autonomous vehicle's performance in each of the plurality of performance metrics. The pass/fail state can be based at least in part on a number and/or degree of deviations from the ideal performance described by the plurality of performance metrics. For example, it may be required that performance of the autonomous vehicle falls within the ideal range of only one or more of the plurality of performance metrics to obtain a passing state. For another example, it may be required that performance of the autonomous vehicle falls within the ideal range of each performance metric for a passing state.

Additionally, in some implementations, the first scenario output can describe or otherwise indicate the actions performed by the autonomous vehicle during the simulation of the autonomous vehicle testing scenario (e.g., any perception, prediction, motion, planned motion, etc.). As an example, the first scenario output can include a time-stepped log of the perception, prediction, motion planning, and any other operations performed by the autonomous vehicle during the autonomous vehicle testing scenario. As another example, the first scenario output can describe any intermediary outputs and/or branching decisions of the autonomous vehicle during the simulation. For example, the first scenario output may describe an intermediary perception output from a machine-learned model among a series of machine-learned models utilized in a perception system of the autonomous vehicle. In such fashion, the first scenario output can be analyzed to determine sources of error within the operations performed by the autonomous vehicle and/or the internal intermediate functions that led to the operations.

An optimization function can be evaluated that evaluates the first scenario output to obtain simulation error data. More particularly, the optimization function (e.g., an error loss function, etc.) can evaluate the differences between the first scenario output (e.g., a pass/fail state, performance values for the plurality of performance metrics, etc.) and ideal values and/or ranges of values for the plurality of performance metrics to obtain the simulation error data. The first scenario output can correspond to a performance metric of the plurality of performance metrics. As an example, the first scenario output may deviate from ideal values for a subset of the plurality of performance metrics. The optimization function (e.g., the derivative of an R2 function, an error loss function, a loss and/or optimization function comprising multiple weighted terms, etc.) can evaluate the first scenario output to obtain the simulation error data. The simulation error data can correspond to, or otherwise indicate, one performance metric of particular importance. Thus, in such fashion, the optimization function can be utilized to obtain simulation error data, which can identify a performance metric of particular importance from the plurality of performance metrics.

Based on the optimization function, the computing system can determine a second sampling rule associated with the performance metric. As an example, the first scenario output can indicate that the simulation of the autonomous vehicle testing scenario failed. Additionally, the first scenario output can identify errors (e.g., value(s) outside of an ideal, etc.) associated with a subset of the plurality of performance metrics. However, many of these errors may be of less importance than others, or may share a causal relationship with other errors (e.g., an error in behavior for a first performance metric may then cause an error in behavior for a second performance metric, etc.). As such, it is particularly important to identify the most influential, or important, errors among the subset of performance metrics. To do so, the optimization function can be evaluated to obtain the simulation error data that corresponds to the performance metric of particular importance from the subset of performance metrics. Based on the optimization function, a second sampling rule can be determined that is configured to emphasize the identified performance metric. More particularly, the second sampling rule can be configured to select parameters that will increase the error associated with the performance metric. For example, if the first sampling rule generated a minor error associated with the parameter (e.g., only slightly outside the range of ideal behavior, etc.), the second sampling rule can be configured to generate a greater error. In such fashion, the optimization function can be used to determine a second sampling rule that narrows the “search space” among the plurality of performance metrics, therefore facilitating identification of the source of the error associated with the performance metric.

A second plurality of testing parameters can be obtained for the autonomous vehicle according to the second sampling rule. In some implementations, the second plurality of testing parameters can include fewer parameters than the first plurality of testing parameters. More particularly, by utilizing the optimization function to narrow the testing parameter search space, the second sampling rule can be more specifically focused on the source of error than the first sampling rule, and can therefore eliminate a number of extraneous or irrelevant testing parameters when sampling for the second plurality of testing parameters.

In some implementations, obtaining the second plurality of testing parameters can include determining a plurality of testing parameters using the second sampling rule. The plurality of testing parameters can be associated with the performance metric of the plurality of performance metrics. As an example, the first plurality of testing parameters may include a large number of actors, each with their own behavior parameters. The simulation error data can correspond to or otherwise identify a performance metric for braking under icy road conditions. The second sampling rule can indicate a rule to ignore actor parameters (e.g., eliminating actors from the simulation, etc.), and instead focus on the plurality of testing parameters that may emphasize the performance metric for braking under icy road conditions (e.g., sampling additional weather parameters, sampling a brake failure or inefficiency parameter, etc.). After identifying the plurality of testing parameters associated with the performance metric, at least a subset of testing parameters from the plurality of testing parameters can be obtained.

In some implementations, the optimization function can include a plurality of weighted optimization terms. Each weighted optimization term can be configured to evaluate a respective performance metric of the plurality of performance metrics (e.g., characterize a respective error loss for each metric, etc.). As an example, the plurality of performance metrics may include a performance metric for braking under icy road conditions. The optimization function may include a weighted optimization term that evaluates the performance metric that is weighted relatively lower than other optimization terms. Because the weighting of the optimization term is relatively low, the simulation error data is relatively unlikely to correspond to the performance metric for braking under icy road conditions. Alternatively, in some implementations, the optimization function may include a plurality of weighted optimization terms that can be respectively associated with a plurality of aspects of the autonomous vehicle testing scenario. As an example, a weighted optimization term of the plurality of weighted optimization terms may be configured to evaluate a subset of the plurality of performance metrics that are associated with an environmental aspect of the autonomous vehicle testing scenario. For example, the weighted optimization term may evaluate a subset of parameters that are related to performing various maneuvers in icy road conditions.

In some implementations, the autonomous vehicle testing scenario can be simulated using the second plurality of testing parameters to obtain a second scenario output. The simulation and obtaining of the second scenario output can be performed using a method identical or substantially similar to those for simulation and obtaining of the first scenario output. In some implementations, the simulation error data can be descriptive of an error value, and the optimization function can be used to evaluate the second scenario output to obtain second simulation error data that is descriptive of a second error value. As an example, the first error value may be descriptive of behavior that is 15% outside a value or range indicative of ideal behavior for the performance metric. The second error value may be descriptive of behavior that is different than the simulation error data (e.g., 45% outside a value or range, 5% outside a value or range, etc.). As such, a change between the first error value and the second error value can indicate that the second sampling rule has affected the performance of the autonomous vehicle for the performance metric.

In some implementations, the second error value can be less than the first error value. To follow the previously described example, the first error value may be descriptive of behavior that is 15% outside a value or range indicative of ideal behavior for the performance metric. The second error value may be descriptive of behavior that only 3% outside a value or range indicative of ideal behavior for the performance metric. If the second error value is less than the first error value, the optimization function can be adjusted to adjust (e.g., increase, decrease, etc.) a weighting of one or more weighted optimization terms of the optimization function. More particularly, if the second sampling rule does not select a plurality of parameters that increase the second error value, it may indicate that the simulation error data incorrectly corresponds or identifies the performance metric, and therefore that one or more weighted optimization terms are improperly weighted. In response, the one or more weighted optimization terms can be adjusted. Once adjusted, the optimization function can be re-evaluated to obtain simulation error data that corresponds to a second performance metric different from the first performance metric.

In some implementations, the second error value can be greater than the first error value. To follow the previously described example, the first error value may be descriptive of behavior that is 15% outside a value or range indicative of ideal behavior for the performance metric. The second error value may be descriptive of behavior that 45% outside a value or range indicative of ideal behavior for the performance metric. If the second error value is greater than the first error value, a third sampling rule can be determined based at least in part on the optimization function and/or the simulation error data. The third sampling rule can be configured to emphasize a second performance metric of the plurality of performance metrics, or can be configured to further emphasize the first performance metric. In such fashion, sampling rules can be iteratively determined until a source of error is found for the performance metric.

In some implementations, the computing system can be or otherwise include a service entity computing system associated with a service entity that facilitates autonomous vehicle implementation. As an example, the service entity can facilitate provision of both first-party and third-party autonomous vehicle implementations (e.g., systems and methods that provide autonomous functionality for autonomous vehicles, etc.). Additionally, in some implementations, the service entity computing system may be updated with parameters obtained based on a sampling rule. As an example, the second plurality of testing parameters can be obtained for the autonomous vehicle testing scenario based on the second sampling rule. One or more components of the service entity computing system (e.g., a vehicle testing system, a vehicle testing knowledge structure, etc.) can be updated with the second plurality of testing parameters. In such fashion, parameters obtained using the second sampling rate can be stored and utilized to facilitate further testing and validation of autonomous vehicle implementations of the service entity.

In some implementations, the computing system and vehicle testing knowledge structure can be or otherwise include a service entity computing system associated with a service entity that facilitates autonomous vehicle services. As an example, the service entity can facilitate provision of both first-party and third-party autonomous vehicle services (e.g., delivery services, transportation services, courier services, aerial transportation services, etc.). Additionally, in some implementations, the autonomous vehicle can be associated with the service entity (e.g., a first-party autonomous vehicle of the service entity, a third-party autonomous vehicle of a vehicle provider that provides services facilitated by the service entity, etc.). Alternatively, in some implementations, the computing system can be or otherwise include an autonomous vehicle computing system of the autonomous vehicle that is configured to implement various autonomous vehicle systems (e.g., motion planning system(s), perception system(s), prediction system(s), etc.).

It should be noted that the examples of the present disclosure are primarily described in the context of a ground-based autonomous vehicle merely to illustrate the various systems and methods of the present disclosure. Rather, the autonomous vehicle(s) of the present disclosure can be any sort or type of autonomous vehicle, including but limited to ground-based autonomous vehicles, water-based autonomous vehicles, and/or aerial autonomous vehicles (e.g., vertical take-off and landing vehicles, etc.). Additionally, in some implementations, systems and methods of the present disclosure can be utilized for non-autonomous vehicles and/or semi-autonomous vehicles.

Various means can be configured to perform the methods and processes described herein. For example, a computing system can include first testing parameter obtaining unit(s), testing scenario simulating unit(s), optimization function evaluating unit(s), sampling rule determining unit(s), second testing parameter obtaining unit(s), and/or other means for performing the operations and functions described herein. In some implementations, one or more of the units may be implemented separately. In some implementations, one or more units may be a part of or included in one or more other units. These means can include processor(s), microprocessor(s), graphics processing unit(s), logic circuit(s), dedicated circuit(s), application-specific integrated circuit(s), programmable array logic, field-programmable gate array(s), controller(s), microcontroller(s), and/or other suitable hardware. The means can also, or alternately, include software control means implemented with a processor or logic circuitry, for example. The means can include or otherwise be able to access memory such as, for example, one or more non-transitory computer-readable storage media, such as random-access memory, read-only memory, electrically erasable programmable read-only memory, erasable programmable read-only memory, flash/other memory device(s), data registrar(s), database(s), and/or other suitable hardware.

The means can be programmed to perform one or more algorithm(s) for carrying out the operations and functions described herein. For instance, the means can be configured to obtain a first plurality of testing parameters for an autonomous vehicle testing scenario (e.g., obtained according to a first sampling rule, etc.). A first testing parameter obtaining unit is an example of means for obtaining a first plurality of testing parameters for an autonomous vehicle testing scenario as described herein.

The means can be configured to simulate an autonomous vehicle testing scenario using a plurality of testing parameters to obtain a first scenario output. For example, the means can be configured to simulate, using the first plurality of testing parameters, the autonomous vehicle testing scenario (e.g., to obtain simulation error data that corresponds to a performance metric of the autonomous vehicle testing scenario, etc.). A testing scenario simulating unit is one example of a means for simulating an autonomous vehicle testing scenario using a plurality of testing parameters as described herein.

The means can be configured to evaluate an optimization function. For example, the means can be configured to evaluate an optimization function that evaluates a first scenario output to obtain simulation error data. The simulation error data can correspond to a performance metric of an autonomous vehicle testing scenario (e.g., a breaking performance metric, etc.). An optimization function evaluating unit is one example of a means for evaluating an optimization function as described herein.

The means can be configured to determine a sampling rule. For example, the means can be configured to determine a second sampling rule associated with a performance metric based at least in part on an optimization function (e.g., a sampling rule configured to emphasize the performance metric, etc.). A sampling rule determining unit is one example of a means for determining a second sampling rule as described herein.

The means can be configured to obtain a second plurality of testing parameters. For example, the means can be configured to obtain a second plurality of testing parameters for an autonomous vehicle testing scenario based at least in part on a second sampling rule (e.g., selecting parameters for the second plurality of testing parameters according to the second sampling rule, etc.). A second testing parameter obtaining unit is one example of a means for obtaining a second plurality of testing parameters as described herein.

The present disclosure provides a number of technical effects and benefits. As one example technical effect and benefit, simulation of autonomous vehicle testing scenarios can often include a substantial number of adjustable parameters (e.g., testing entity location/pose/behavior, environmental conditions, etc.). Due to the large number of adjustable parameters, it can be substantially difficult to locate the source of errors associated with various performance metrics of the testing scenario. As such, conventional techniques generally necessitate a broad, randomized parameter sampling strategy to locate the source of an error, leading to prohibitively inefficient computational costs. However, by utilizing an optimization function to identify key performance metrics, systems and methods of the present disclosure allow for determination of a sampling strategy that narrows the parameter sampling space iteratively, significantly reducing the number of simulations to be performed and therefore substantially reducing computational resources required for simulation of autonomous vehicle testing scenarios (e.g., memory, processor instruction cycles, specialized hardware, etc.).

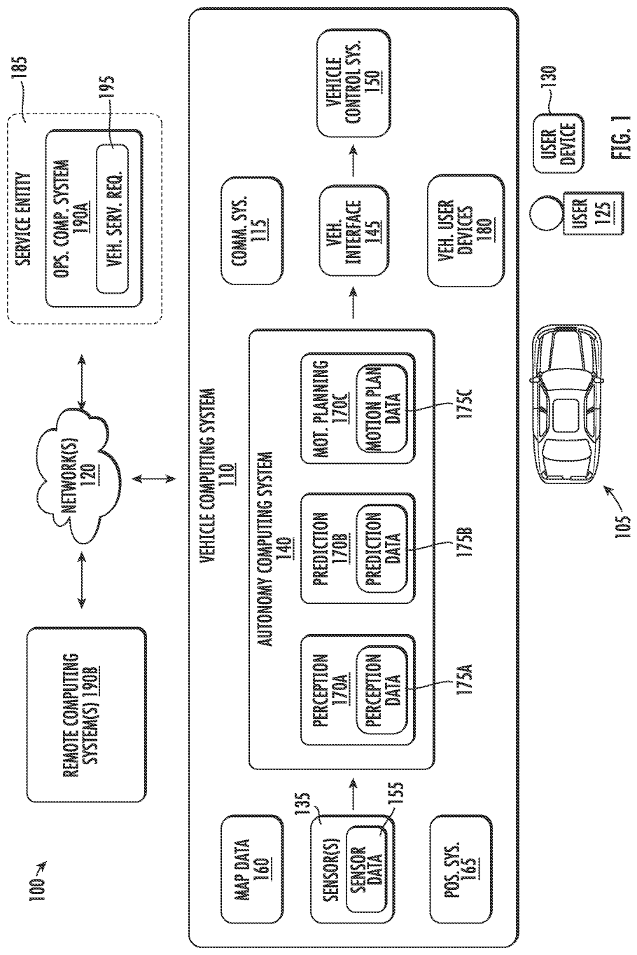

With reference now to the FIGS., example aspects of the present disclosure will be discussed in further detail. FIG. 1 depicts a block diagram of an example system 100 for controlling and communicating with a vehicle according to example aspects of the present disclosure. As illustrated, FIG. 1 shows a system 100 that can include a vehicle 105 and a vehicle computing system 110 associated with the vehicle 105. The vehicle computing system 100 can be located onboard the vehicle 105 (e.g., it can be included on and/or within the vehicle 105).

The vehicle 105 incorporating the vehicle computing system 100 can be various types of vehicles. For instance, the vehicle 105 can be an autonomous vehicle. The vehicle 105 can be a ground-based autonomous vehicle (e.g., car, truck, bus, etc.). The vehicle 105 can be an air-based autonomous vehicle (e.g., airplane, helicopter, vertical take-off and lift (VTOL) aircraft, etc.). The vehicle 105 can be a light weight elective vehicle (e.g., bicycle, scooter, etc.). The vehicle 105 can be another type of vehicles (e.g., watercraft, etc.). The vehicle 105 can drive, navigate, operate, etc. with minimal and/or no interaction from a human operator (e.g., driver, pilot, etc.). In some implementations, a human operator can be omitted from the vehicle 105 (and/or also omitted from remote control of the vehicle 105). In some implementations, a human operator can be included in the vehicle 105.

The vehicle 105 can be configured to operate in a plurality of operating modes. The vehicle 105 can be configured to operate in a fully autonomous (e.g., self-driving) operating mode in which the vehicle 105 is controllable without user input (e.g., can drive and navigate with no input from a human operator present in the vehicle 105 and/or remote from the vehicle 105). The vehicle 105 can operate in a semi-autonomous operating mode in which the vehicle 105 can operate with some input from a human operator present in the vehicle 105 (and/or a human operator that is remote from the vehicle 105). The vehicle 105 can enter into a manual operating mode in which the vehicle 105 is fully controllable by a human operator (e.g., human driver, pilot, etc.) and can be prohibited and/or disabled (e.g., temporary, permanently, etc.) from performing autonomous navigation (e.g., autonomous driving, flying, etc.). The vehicle 105 can be configured to operate in other modes such as, for example, park and/or sleep modes (e.g., for use between tasks/actions such as waiting to provide a vehicle service, recharging, etc.). In some implementations, the vehicle 105 can implement vehicle operating assistance technology (e.g., collision mitigation system, power assist steering, etc.), for example, to help assist the human operator of the vehicle 105 (e.g., while in a manual mode, etc.).

To help maintain and switch between operating modes, the vehicle computing system 110 can store data indicative of the operating modes of the vehicle 105 in a memory onboard the vehicle 105. For example, the operating modes can be defined by an operating mode data structure (e.g., rule, list, table, etc.) that indicates one or more operating parameters for the vehicle 105, while in the particular operating mode. For example, an operating mode data structure can indicate that the vehicle 105 is to autonomously plan its motion when in the fully autonomous operating mode. The vehicle computing system 110 can access the memory when implementing an operating mode.

The operating mode of the vehicle 105 can be adjusted in a variety of manners. For example, the operating mode of the vehicle 105 can be selected remotely, off-board the vehicle 105. For example, a remote computing system (e.g., of a vehicle provider and/or service entity associated with the vehicle 105) can communicate data to the vehicle 105 instructing the vehicle 105 to enter into, exit from, maintain, etc. an operating mode. By way of example, such data can instruct the vehicle 105 to enter into the fully autonomous operating mode.

In some implementations, the operating mode of the vehicle 105 can be set onboard and/or near the vehicle 105. For example, the vehicle computing system 110 can automatically determine when and where the vehicle 105 is to enter, change, maintain, etc. a particular operating mode (e.g., without user input). Additionally, or alternatively, the operating mode of the vehicle 105 can be manually selected via one or more interfaces located onboard the vehicle 105 (e.g., key switch, button, etc.) and/or associated with a computing device proximate to the vehicle 105 (e.g., a tablet operated by authorized personnel located near the vehicle 105). In some implementations, the operating mode of the vehicle 105 can be adjusted by manipulating a series of interfaces in a particular order to cause the vehicle 105 to enter into a particular operating mode.

The vehicle computing system 110 can include one or more computing devices located onboard the vehicle 105. For example, the computing device(s) can be located on and/or within the vehicle 105. The computing device(s) can include various components for performing various operations and functions. For instance, the computing device(s) can include one or more processors and one or more tangible, non-transitory, computer readable media (e.g., memory devices, etc.). The one or more tangible, non-transitory, computer readable media can store instructions that when executed by the one or more processors cause the vehicle 105 (e.g., its computing system, one or more processors, etc.) to perform operations and functions, such as those described herein for controlling an autonomous vehicle, communicating with other computing systems, simulating autonomous vehicle testing scenario(s), determining sampling rule(s), etc.

The vehicle 105 can include a communications system 115 configured to allow the vehicle computing system 110 (and its computing device(s)) to communicate with other computing devices. The communications system 115 can include any suitable components for interfacing with one or more network(s) 120, including, for example, transmitters, receivers, ports, controllers, antennas, and/or other suitable components that can help facilitate communication. In some implementations, the communications system 115 can include a plurality of components (e.g., antennas, transmitters, and/or receivers) that allow it to implement and utilize multiple-input, multiple-output (MIMO) technology and communication techniques.

The vehicle computing system 110 can use the communications system 115 to communicate with one or more computing device(s) that are remote from the vehicle 105 over one or more networks 120 (e.g., via one or more wireless signal connections). The network(s) 120 can exchange (send or receive) signals (e.g., electronic signals), data (e.g., data from a computing device), and/or other information and include any combination of various wired (e.g., twisted pair cable) and/or wireless communication mechanisms (e.g., cellular, wireless, satellite, microwave, and radio frequency) and/or any desired network topology (or topologies). For example, the network(s) 120 can include a local area network (e.g., intranet), wide area network (e.g., Internet), wireless LAN network (e.g., via Wi-Fi), cellular network, a SATCOM network, VHF network, a HF network, a WiMAX based network, and/or any other suitable communication network (or combination thereof) for transmitting data to and/or from the vehicle 105 and/or among computing systems.

In some implementations, the communications system 115 can also be configured to enable the vehicle 105 to communicate with and/or provide and/or receive data and/or signals from a remote computing device associated with a user 125 and/or an item (e.g., an item to be picked-up for a courier service). For example, the communications system 115 can allow the vehicle 105 to locate and/or exchange communications with a user device 130 of a user 125. In some implementations, the communications system 115 can allow communication among one or more of the system(s) on-board the vehicle 105.

As shown in FIG. 1, the vehicle 105 can include one or more sensors 135, an autonomy computing system 140, a vehicle interface 145, one or more vehicle control systems 150, and other systems, as described herein. One or more of these systems can be configured to communicate with one another via one or more communication channels. The communication channel(s) can include one or more data buses (e.g., controller area network (CAN)), on-board diagnostics connector (e.g., OBD-II), and/or a combination of wired and/or wireless communication links. The onboard systems can send and/or receive data, messages, signals, etc. amongst one another via the communication channel(s).

The sensor(s) 135 can be configured to acquire sensor data 155. The sensor(s) 135 can be external sensors configured to acquire external sensor data. This can include sensor data associated with the surrounding environment of the vehicle 105. The surrounding environment of the vehicle 105 can include/be represented in the field of view of the sensor(s) 135. For instance, the sensor(s) 135 can acquire image and/or other data of the environment outside of the vehicle 105 and within a range and/or field of view of one or more of the sensor(s) 135. The sensor(s) 135 can include one or more Light Detection and Ranging (LIDAR) systems, one or more Radio Detection and Ranging (RADAR) systems, one or more cameras (e.g., visible spectrum cameras, infrared cameras, etc.), one or more motion sensors, one or more audio sensors (e.g., microphones, etc.), and/or other types of imaging capture devices and/or sensors. The one or more sensors can be located on various parts of the vehicle 105 including a front side, rear side, left side, right side, top, and/or bottom of the vehicle 105. The sensor data 155 can include image data (e.g., 2D camera data, video data, etc.), RADAR data, LIDAR data (e.g., 3D point cloud data, etc.), audio data, and/or other types of data. The vehicle 105 can also include other sensors configured to acquire data associated with the vehicle 105. For example, the vehicle 105 can include inertial measurement unit(s), wheel odometry devices, and/or other sensors.

In some implementations, the sensor(s) 135 can include one or more internal sensors. The internal sensor(s) can be configured to acquire sensor data 155 associated with the interior of the vehicle 105. For example, the internal sensor(s) can include one or more cameras, one or more infrared sensors, one or more motion sensors, one or more weight sensors (e.g., in a seat, in a trunk, etc.), and/or other types of sensors. The sensor data 155 acquired via the internal sensor(s) can include, for example, image data indicative of a position of a passenger or item located within the interior (e.g., cabin, trunk, etc.) of the vehicle 105. This information can be used, for example, to ensure the safety of the passenger, to prevent an item from being left by a passenger, confirm the cleanliness of the vehicle 105, remotely assist a passenger, etc.

In some implementations, the sensor data 155 can be indicative of one or more objects within the surrounding environment of the vehicle 105. The object(s) can include, for example, vehicles, pedestrians, bicycles, and/or other objects. The object(s) can be located in front of, to the rear of, to the side of, above, below the vehicle 105, etc. The sensor data 155 can be indicative of locations associated with the object(s) within the surrounding environment of the vehicle 105 at one or more times. The object(s) can be static objects (e.g., not in motion) and/or dynamic objects/actors (e.g., in motion or likely to be in motion) in the vehicle's environment. The sensor(s) 135 can provide the sensor data 155 to the autonomy computing system 140.

In addition to the sensor data 155, the autonomy computing system 140 can obtain map data 160. The map data 160 can provide detailed information about the surrounding environment of the vehicle 105 and/or the geographic area in which the vehicle was, is, and/or will be located. For example, the map data 160 can provide information regarding: the identity and location of different roadways, road segments, buildings, or other items or objects (e.g., lampposts, crosswalks and/or curb); the location and directions of traffic lanes (e.g., the location and direction of a parking lane, a turning lane, a bicycle lane, or other lanes within a particular roadway or other travel way and/or one or more boundary markings associated therewith); traffic control data (e.g., the location and instructions of signage, traffic lights, and/or other traffic control devices); obstruction information (e.g., temporary or permanent blockages, etc.); event data (e.g., road closures/traffic rule alterations due to parades, concerts, sporting events, etc.); nominal vehicle path data (e.g., indicate of an ideal vehicle path such as along the center of a certain lane, etc.); and/or any other map data that provides information that assists the vehicle computing system 110 in processing, analyzing, and perceiving its surrounding environment and its relationship thereto. In some implementations, the map data 160 can include high definition map data. In some implementations, the map data 160 can include sparse map data indicative of a limited number of environmental features (e.g., lane boundaries, etc.). In some implementations, the map data can be limited to geographic area(s) and/or operating domains in which the vehicle 105 (or autonomous vehicles generally) may travel (e.g., due to legal/regulatory constraints, autonomy capabilities, and/or other factors).

The vehicle 105 can include a positioning system 165. The positioning system 165 can determine a current position of the vehicle 105. This can help the vehicle 105 localize itself within its environment. The positioning system 165 can be any device or circuitry for analyzing the position of the vehicle 105. For example, the positioning system 165 can determine position by using one or more of inertial sensors (e.g., inertial measurement unit(s), etc.), a satellite positioning system, based on IP address, by using triangulation and/or proximity to network access points or other network components (e.g., cellular towers, WiFi access points, etc.) and/or other suitable techniques. The position of the vehicle 105 can be used by various systems of the vehicle computing system 110 and/or provided to a remote computing system. For example, the map data 160 can provide the vehicle 105 relative positions of the elements of a surrounding environment of the vehicle 105. The vehicle 105 can identify its position within the surrounding environment (e.g., across six axes, etc.) based at least in part on the map data 160. For example, the vehicle computing system 110 can process the sensor data 155 (e.g., LIDAR data, camera data, etc.) to match it to a map of the surrounding environment to get an understanding of the vehicle's position within that environment. Data indicative of the vehicle's position can be stored, communicated to, and/or otherwise obtained by the autonomy computing system 140.

The autonomy computing system 140 can perform various functions for autonomously operating the vehicle 105. For example, the autonomy computing system 140 can perform the following functions: perception 170A, prediction 170B, and motion planning 170C. For example, the autonomy computing system 130 can obtain the sensor data 155 via the sensor(s) 135, process the sensor data 155 (and/or other data) to perceive its surrounding environment, predict the motion of objects within the surrounding environment, and generate an appropriate motion plan through such surrounding environment. In some implementations, these autonomy functions can be performed by one or more sub-systems such as, for example, a perception system, a prediction system, a motion planning system, and/or other systems that cooperate to perceive the surrounding environment of the vehicle 105 and determine a motion plan for controlling the motion of the vehicle 105 accordingly. In some implementations, one or more of the perception, prediction, and/or motion planning functions 170A, 170B, 170C can be performed by (and/or combined into) the same system and/or via shared computing resources. In some implementations, one or more of these functions can be performed via difference sub-systems. As further described herein, the autonomy computing system 140 can communicate with the one or more vehicle control systems 150 to operate the vehicle 105 according to the motion plan (e.g., via the vehicle interface 145, etc.).

The vehicle computing system 110 (e.g., the autonomy computing system 140) can identify one or more objects that within the surrounding environment of the vehicle 105 based at least in part on the sensor data 135 and/or the map data 160. The objects perceived within the surrounding environment can be those within the field of view of the sensor(s) 135 and/or predicted to be occluded from the sensor(s) 135. This can include object(s) not in motion or not predicted to move (static objects) and/or object(s) in motion or predicted to be in motion (dynamic objects/actors). The vehicle computing system 110 (e.g., performing the perception function 170C, using a perception system, etc.) can process the sensor data 155, the map data 160, etc. to obtain perception data 175A. The vehicle computing system 110 can generate perception data 175A that is indicative of one or more states (e.g., current and/or past state(s)) of one or more objects that are within a surrounding environment of the vehicle 105. For example, the perception data 175A for each object can describe (e.g., for a given time, time period) an estimate of the object's: current and/or past location (also referred to as position); current and/or past speed/velocity; current and/or past acceleration; current and/or past heading; current and/or past orientation; size/footprint (e.g., as represented by a bounding shape, object highlighting, etc.); class (e.g., pedestrian class vs. vehicle class vs. bicycle class, etc.), the uncertainties associated therewith, and/or other state information. The vehicle computing system 110 can utilize one or more algorithms and/or machine-learned model(s) that are configured to identify object(s) based at least in part on the sensor data 155. This can include, for example, one or more neural networks trained to identify object(s) within the surrounding environment of the vehicle 105 and the state data associated therewith. The perception data 175A can be utilized for the prediction function 175B of the autonomy computing system 140.

The vehicle computing system 110 can be configured to predict a motion of the object(s) within the surrounding environment of the vehicle 105. For instance, the vehicle computing system 110 can generate prediction data 175B associated with such object(s). The prediction data 175B can be indicative of one or more predicted future locations of each respective object. For example, the prediction system 175B can determine a predicted motion trajectory along which a respective object is predicted to travel over time. A predicted motion trajectory can be indicative of a path that the object is predicted to traverse and an associated timing with which the object is predicted to travel along the path. The predicted path can include and/or be made up of a plurality of way points. In some implementations, the prediction data 175B can be indicative of the speed and/or acceleration at which the respective object is predicted to travel along its associated predicted motion trajectory. The vehicle computing system 110 can utilize one or more algorithms and/or machine-learned model(s) that are configured to predict the future motion of object(s) based at least in part on the sensor data 155, the perception data 175A, map data 160, and/or other data. This can include, for example, one or more neural networks trained to predict the motion of the object(s) within the surrounding environment of the vehicle 105 based at least in part on the past and/or current state(s) of those objects as well as the environment in which the objects are located (e.g., the lane boundary in which it is travelling, etc.). The prediction data 175B can be utilized for the motion planning function 170C of the autonomy computing system 140.

The vehicle computing system 110 can determine a motion plan for the vehicle 105 based at least in part on the perception data 175A, the prediction data 175B, and/or other data. For example, the vehicle computing system 110 can generate motion planning data 175C indicative of a motion plan. The motion plan can include vehicle actions (e.g., speed(s), acceleration(s), other actions, etc.) with respect to one or more of the objects within the surrounding environment of the vehicle 105 as well as the objects' predicted movements. The motion plan can include one or more vehicle motion trajectories that indicate a path for the vehicle 105 to follow. A vehicle motion trajectory can be of a certain length and/or time range. A vehicle motion trajectory can be defined by one or more way points (with associated coordinates). The planned vehicle motion trajectories can indicate the path the vehicle 105 is to follow as it traverses a route from one location to another. Thus, the vehicle computing system 110 can take into account a route/route data when performing the motion planning function 170C.

The vehicle motion planning system can include an optimization algorithm, machine-learned model, etc. that considers cost data associated with a vehicle action as well as other objective functions (e.g., cost functions based on speed limits, traffic lights, etc.), if any, to determine optimized variables that make up the motion plan. The vehicle computing system 110 can determine that the vehicle 105 can perform a certain action (e.g., pass an object, etc.) without increasing the potential risk to the vehicle 105 and/or violating any traffic laws (e.g., speed limits, lane boundaries, signage, etc.). For instance, the vehicle computing system 110 can evaluate the predicted motion trajectories of one or more objects during its cost data analysis to help determine an optimized vehicle trajectory through the surrounding environment. The motion planning system 180 can generate cost data associated with such trajectories. In some implementations, one or more of the predicted motion trajectories and/or perceived objects may not ultimately change the motion of the vehicle 105 (e.g., due to an overriding factor). In some implementations, the motion plan may define the vehicle's motion such that the vehicle 105 avoids the object(s), reduces speed to give more leeway to one or more of the object(s), proceeds cautiously, performs a stopping action, passes an object, queues behind/in front of an object, etc.

The vehicle computing system 110 can be configured to continuously update the vehicle's motion plan and a corresponding planned vehicle motion trajectories. For example, in some implementations, the vehicle computing system 110 can generate new motion planning data 175C/motion plan(s) for the vehicle 105 (e.g., multiple times per second, etc.). Each new motion plan can describe a motion of the vehicle 105 over the next planning period (e.g., next several seconds, etc.). Moreover, a new motion plan may include a new planned vehicle motion trajectory. Thus, in some implementations, the vehicle computing system 110 can continuously operate to revise or otherwise generate a short-term motion plan based on the currently available data. Once the optimization planner has identified the optimal motion plan (or some other iterative break occurs), the optimal motion plan (and the planned motion trajectory) can be selected and executed by the vehicle 105.

The vehicle computing system 110 can cause the vehicle 105 to initiate a motion control in accordance with at least a portion of the motion planning data 175C. A motion control can be an operation, action, etc. that is associated with controlling the motion of the vehicle 105. For instance, the motion planning data 175C can be provided to the vehicle control system(s) 150 of the vehicle 105. The vehicle control system(s) 150 can be associated with a vehicle interface 145 that is configured to implement a motion plan. The vehicle interface 145 can serve as an interface/conduit between the autonomy computing system 140 and the vehicle control systems 150 of the vehicle 105 and any electrical/mechanical controllers associated therewith. The vehicle interface 145 can, for example, translate a motion plan into instructions for the appropriate vehicle control component (e.g., acceleration control, brake control, steering control, etc.). By way of example, the vehicle interface 145 can translate a determined motion plan into instructions to adjust the steering of the vehicle 105 “X” degrees, apply a certain magnitude of braking force, increase/decrease speed, etc. The vehicle interface 145 can help facilitate the responsible vehicle control (e.g., braking control system, steering control system, acceleration control system, etc.) to execute the instructions and implement a motion plan (e.g., by sending control signal(s), making the translated plan available, etc.). This can allow the vehicle 105 to autonomously travel within the vehicle's surrounding environment.

The vehicle computing system 110 can store other types of data. For example, an indication, record, and/or other data indicative of the state of the vehicle (e.g., its location, motion trajectory, health information, etc.), the state of one or more users (e.g., passengers, operators, etc.) of the vehicle, and/or the state of an environment including one or more objects (e.g., the physical dimensions and/or appearance of the one or more objects, locations, predicted motion, etc.) can be stored locally in one or more memory devices of the vehicle 105. Additionally, the vehicle 105 can communicate data indicative of the state of the vehicle, the state of one or more passengers of the vehicle, and/or the state of an environment to a computing system that is remote from the vehicle 105, which can store such information in one or more memories remote from the vehicle 105. Moreover, the vehicle 105 can provide any of the data created and/or store onboard the vehicle 105 to another vehicle.

The vehicle computing system 110 can include the one or more vehicle user devices 180. For example, the vehicle computing system 110 can include one or more user devices with one or more display devices located onboard the vehicle 105. A display device (e.g., screen of a tablet, laptop, and/or smartphone) can be viewable by a user of the vehicle 105 that is located in the front of the vehicle 105 (e.g., driver's seat, front passenger seat). Additionally, or alternatively, a display device can be viewable by a user of the vehicle 105 that is located in the rear of the vehicle 105 (e.g., a back passenger seat). The user device(s) associated with the display devices can be any type of user device such as, for example, a table, mobile phone, laptop, etc. The vehicle user device(s) 180 can be configured to function as human-machine interfaces. For example, the vehicle user device(s) 180 can be configured to obtain user input, which can then be utilized by the vehicle computing system 110 and/or another computing system (e.g., a remote computing system, etc.). For example, a user (e.g., a passenger for transportation service, a vehicle operator, etc.) of the vehicle 105 can provide user input to adjust a destination location of the vehicle 105. The vehicle computing system 110 and/or another computing system can update the destination location of the vehicle 105 and the route associated therewith to reflect the change indicated by the user input.

The vehicle 105 can be configured to perform vehicle services for one or a plurality of different service entities 185. A vehicle 105 can perform a vehicle service by, for example and as further described herein, travelling (e.g., traveling autonomously) to a location associated with a requested vehicle service, allowing user(s) and/or item(s) to board or otherwise enter the vehicle 105, transporting the user(s) and/or item(s), allowing the user(s) and/or item(s) to deboard or otherwise exit the vehicle 105, etc. In this way, the vehicle 105 can provide the vehicle service(s) for a service entity to a user.

A service entity 185 can be associated with the provision of one or more vehicle services. For example, a service entity can be an individual, a group of individuals, a company (e.g., a business entity, organization, etc.), a group of entities (e.g., affiliated companies), and/or another type of entity that offers and/or coordinates the provision of one or more vehicle services to one or more users. For example, a service entity can offer vehicle service(s) to users via one or more software applications (e.g., that are downloaded onto a user computing device), via a website, and/or via other types of interfaces that allow a user to request a vehicle service. As described herein, the vehicle services can include transportation services (e.g., by which a vehicle transports user(s) from one location to another), delivery services (e.g., by which a vehicle transports/delivers item(s) to a requested destination location), courier services (e.g., by which a vehicle retrieves item(s) from a requested origin location and transports/delivers the item to a requested destination location), and/or other types of services. The vehicle services can be wholly performed by the vehicle 105 (e.g., travelling from the user/item origin to the ultimate destination, etc.) or performed by one or more vehicles and/or modes of transportation (e.g., transferring the user/item at intermediate transfer points, etc.).

An operations computing system 190A of the service entity 185 can help to coordinate the performance of vehicle services by autonomous vehicles. The operations computing system 190A can include and/or implement one or more service platforms of the service entity. The operations computing system 190A can include one or more computing devices. The computing device(s) can include various components for performing various operations and functions. For instance, the computing device(s) can include one or more processors and one or more tangible, non-transitory, computer readable media (e.g., memory devices, etc.). The one or more tangible, non-transitory, computer readable media can store instructions that when executed by the one or more processors cause the operations computing system 190 (e.g., its one or more processors, etc.) to perform operations and functions, such as those described herein matching users and vehicles/vehicle fleets, deploying vehicles, facilitating the provision of vehicle services via autonomous vehicles, communicating with other computing systems, simulating autonomous vehicle testing scenario(s), determining sampling rule(s), etc.

A user 125 can request a vehicle service from a service entity 185. For example, the user 125 can provide user input to a user device 130 to request a vehicle service (e.g., via a user interface associated with a mobile software application of the service entity 185 running on the user device 130). The user device 130 can communicate data indicative of a vehicle service request 195 to the operations computing system 190A associated with the service entity 185 (and/or another associated computing system that can then communicate data to the operations computing system 190A). The vehicle service request 195 can be associated with a user. The associated user can be the one that submits the vehicle service request (e.g., via an application on the user device 130). In some implementations, the user may not be the user that submits the vehicle service request. The vehicle service request can be indicative of the user. For example, the vehicle service request can include an identifier associated with the user and/or the user's profile/account with the service entity 185. The vehicle service request 195 can be generated in a manner that avoids the use of personally identifiable information and/or allows the user to control the types of information included in the vehicle service request 195. The vehicle service request 195 can also be generated, communicated, stored, etc. in a secure manner to protect information.

The vehicle service request 195 can indicate various types of information. For example, the vehicle service request 194 can indicate the type of vehicle service that is desired (e.g., a transportation service, a delivery service, a courier service, etc.), one or more locations (e.g., an origin location, a destination location, etc.), timing constraints (e.g., pick-up time, drop-off time, deadlines, etc.), and/or geographic constraints (e.g., to stay within a certain area, etc.). The service request 195 can indicate a type/size/class of vehicle such as, for example, a sedan, an SUV, luxury vehicle, standard vehicle, etc. The service request 195 can indicate a product of the service entity 185. For example, the service request 195 can indicate that the user is requesting a transportation pool product by which the user would potentially share the vehicle (and costs) with other users/items. In some implementations, the service request 195 can explicitly request for the vehicle service to be provided by an autonomous vehicle or a human-driven vehicle. In some implementations, the service request 195 can indicate a number of users that will be riding in the vehicle/utilizing the vehicle service. In some implementations, the service request 195 can indicate preferences/special accommodations of an associated user (e.g., music preferences, climate preferences, wheelchair accessibility, etc.) and/or other information.

The operations computing system 190A of the service entity 185 can process the data indicative of the vehicle service request 195 and generate a vehicle service assignment that is associated with the vehicle service request. The operations computing system can identify one or more vehicles that may be able to perform the requested vehicle services to the user 195. The operations computing system 190A can identify which modes of transportation are available to a user for the requested vehicle service (e.g., light electric vehicles, human-drive vehicles, autonomous vehicles, aerial vehicle, etc.) and/or the number of transportation modes/legs of a potential itinerary of the user for completing the vehicle service (e.g., single or plurality of modes, single or plurality of legs, etc.). For example, the operations computing system 190A can determined which autonomous vehicle(s) are online with the service entity 185 (e.g., available for a vehicle service assignment, addressing a vehicle service assignment, etc.) to help identify which autonomous vehicle(s) would be able to provide the vehicle service.

The operations computing system 190A and/or the vehicle computing system 110 can communicate with one or more other computing systems 190B that are remote from the vehicle 105. This can include, for example, computing systems associated with government functions (e.g., emergency services, regulatory bodies, etc.), computing systems associated with vehicle providers other than the service entity, computing systems of other vehicles (e.g., other autonomous vehicles, aerial vehicles, etc.). Communication with the other computing systems 190B can occur via the network(s) 120.

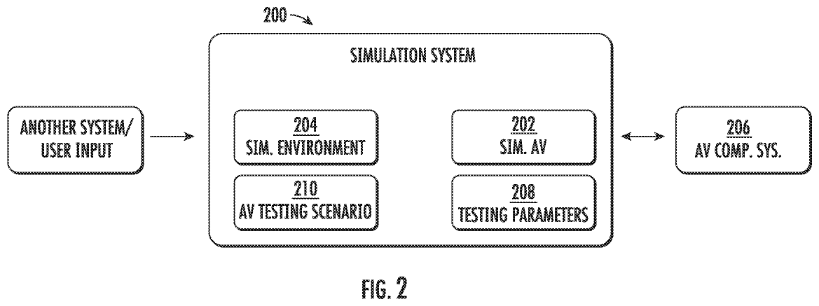

The operations computing system 190A can simulate and/or facilitate simulation of autonomous driving functionality (e.g., processing operations performed by the vehicle computing system(s) 110, etc.). For example, with reference to FIG. 2, the operations computing system 190A can include, communicate with, access, etc. a simulation system 200 configured to simulate an autonomous vehicle testing scenario (e.g., using one or more corresponding vehicle testing tuples, etc.). As an example, the operations computing system 190A can utilize, communicate with, etc. a simulation system 200 to enable simulation of a simulated autonomous vehicle 202 within a simulation environment 204 including a geographic area. Various systems and devices configured to control the operation of the vehicle can be simulated. For example, a simulated autonomous vehicle 202 may include a simulation of any portion or all of an autonomous vehicle. For example, an autonomy software stack of an autonomous vehicle or other computer-based systems of the autonomous vehicle can be simulated. The autonomy software stack can include similar or the same functions as the autonomy system 140 of FIG. 1 and can be provided via an autonomous vehicle computing system 206 used for simulation. This can be utilized to generate an instance and control of a simulated autonomous vehicle 202 within the simulation environment 204. One or more instances of a simulated autonomous vehicle 202 can be provisioned and deployed at one or more computing devices (e.g., operations computing system 190A, remote computing system(s) 190B, etc.).

The simulation computing system 200 can obtain a plurality of testing parameters 208 (e.g., from a vehicle testing knowledge structure, etc.) according to a sampling rule. In some implementations, each of one or more predefined vehicle testing scenarios 210 (e.g., of corresponding scenario type(s), etc.) can be provided as a respective scenario object alongside the at least one instance of the simulated autonomous vehicle 202 in example embodiments. Using the simulation system 200, one or more vehicle service simulations can be performed using the instance of the simulated autonomous vehicle 202 and the plurality of testing parameters 208 obtained according to the sampling rule. Data indicative of simulation of the vehicle testing scenario 210 can be generated and/or stored by the simulation system. In this manner, a vehicle service-flow and/or autonomous vehicle can be quickly evaluated and debugged prior to actual deployment of an autonomous vehicle (e.g., in association with the vehicle service). In some examples, data can be exchanged using one or more testing libraries.

The simulation system 200 can obtain data defining at least one instance of a simulated autonomous vehicle. In some examples, a user (e.g., a developer, a testing engineer, etc.) and/or a third-party vehicle provider computing system (e.g., remote computing system(s) 190B, etc.) may define the at least one instance of the simulated autonomous vehicle 202 using one or more interfaces provided by the operations computing system 190A (e.g., via network(s) 120, etc.). In this manner, the user and/or third-party vehicle provider computing system (e.g., remote computing system(s) 190B, etc.) may provision a new simulated autonomous vehicle 202 to be evaluated in accordance with one or more vehicle services. The data defining the at least one instance of the simulated autonomous vehicle may include data defining one or more capabilities of the autonomous vehicle, a state of the autonomous vehicle, etc. Such information can be provided from another system in communication with the simulation system 200 and/or via user input. In some implementations, the simulation system 200 can provide simulation as a service to third-parties.

The instance(s) of the simulated autonomous vehicle 202 can be deployed as a network service in some examples, such as for one or more servers in direct communication with the operations computing system 190A (e.g., remote computing system(s) 190B, etc.). The simulated autonomous vehicle instances can be communicated with using various communication protocols (e.g., via network(s) 120, etc.). In some examples, each instance of a simulated autonomous vehicle 202 may include an interface such as an interface programmed in a software development kit (SDK) that is similar to or the same as an interface (e.g., SDK) included within an actual autonomous vehicle used to provide a vehicle service. The interface may enable the operations computing system 190A to issue instructions to the autonomous vehicle instance to accept a service request, reject a service request, update the pose field of the autonomous vehicle instance, etc.

The simulation system 200 can obtain a plurality of testing parameters 208 for simulation of a testing scenario 210 according to a sampling rule. For example, the plurality of testing parameters 208 (e.g., a tuple of parameters, etc.) may define a dispatch of a vehicle service to an instance of a simulated autonomous vehicle 202. The testing parameters 208 may also instruct the instance of the simulated autonomous vehicle 202 to accept or reject a service request. The testing parameters 208 may additionally indicate service-flow updates and/or location updates. The testing parameters may indicate a route from a pick-up location to a drop-off location in example embodiments. In some examples, the operations computing system 190A may obtain the parameters and/or the sampling rule using the simulation system 200.

The simulation system 200can simulate testing scenarios 210 using an instantiated instance of the simulated autonomous vehicle 202. A testing scenario 210 can be simulated based at least in part on the testing parameters 208 obtained based on a sampling rule. As described previously, the testing parameters 208 can define a step (also referred to as a tick) duration, a vehicle movement strategy (e.g., no operation, move to pickup and drop-off locations, move using a constant speed and straight line, or move using a constant number of steps, etc.), vehicle callbacks (e.g., always reject, always accept, no operation, etc.), and/or a maximum number of steps. The simulation of the vehicle testing scenario 210 can result in a termination condition in response to a vehicle entering a terminal state (e.g., vehicle is offline), a vehicle performing a terminating transition (e.g., door open), a termination command being executed, or a maximum number of steps being reached.

In accordance with some aspects of the disclosed technology, the simulation system 200 may determine and store metrics for the simulation of the autonomous vehicle testing scenario 210. Example metrics may include for interface calls (e.g., programmed in an SDK): a number of succeeded method attempts; a number of failed method attempts; a latency of attempts; and/or a number of bytes in and out. Example metrics for the session may further include a vehicle state heartbeat; a state using a 1/0 gauge; an exception or equivalent (e.g., exception tag); all exceptions; and vehicle uptime.

More particularly, the simulation system 200 can be configured to generate a simulated environment 204 and simulate a testing scenario 210 within that simulated environment 204. For instance, the plurality of testing parameters 208 can be obtained based on a sampling rule. The sampling rule can be configured to emphasize a certain aspect of the testing scenario 210. As described previously, the plurality of testing parameters 208 can specify various characteristics of the simulated environment 204 that include, for example: a general type of geographic area for the simulated environment 204 (e.g., highway, urban, rural, etc.); a specific geographic area for the simulated environment 204 (e.g., beltway of City A, downtown of City B, country side of County C, etc.); one or more geographic features (e.g., trees, benches, obstructions, buildings, boundaries, exit ramps, etc.) and their corresponding positions in the simulated environment 204; a time of day; one or more weather conditions; one or more initial conditions of the simulated object(s) within the simulated environment 204 (e.g., initial position, heading, speed, etc.); a type of each simulated object (e.g., vehicle, bicycle, pedestrian, etc.); a geometry of each simulated object (e.g., shape, size etc.); one or more initial conditions of the simulated autonomous vehicle 202 within the simulated environment 204 (e.g., initial position, heading, speed, etc.); a type of the simulated autonomous vehicle 202 (e.g., sedan, sport utility, etc.); a geometry of the simulated autonomous vehicle 202 (e.g., shape, size etc.); operating condition of each simulated object (e.g., correct turn signal usage vs. no turn signal usage, functional brake lights vs. one or more brake lights that are non-functional, etc.) and/or other data associated with the simulated environment 202. The simulation system 200 can obtain the data indicative of these initial input(s) and generate the simulated environment 204 accordingly. In some implementations, one or more templates can be available for selection, which provide a standardized or otherwise pre-configured simulated environment 204 and the user can select one of the templates and optionally modify the template environment with additional user input.

The simulation system 200 can present a visual representation of the simulated environment 204 via a user interface (e.g., graphical user interface) on a display device (e.g., user device 130, etc.). The simulated environment 204 can include the simulated object and the simulated autonomous vehicle 202 (e.g., as visual representations on the user interface). For example, the simulated environment 204 can be a highway environment in which the simulated autonomous vehicle 202 is travelling in a traffic lane adjacent to a simulated object (e.g., a simulated vehicle). In another example, the simulated environment 204 can be an urban intersection environment in which the simulated autonomous vehicle 202 is travelling along a travel way that approaches a crosswalk and a simulated object (e.g., a simulated pedestrian) can be positioned near the crosswalk. The simulation system 200 and display device can operate to provide various different views of the simulated environment 204 including, as examples, a bird's eye or overhead view of the simulated environment 204, a view rendered from the vantage point of the object (e.g., from the driver's seat of the simulated object), a view rendered from the vantage point of the autonomous vehicle, and/or other views of the simulated environment 204.

The plurality of testing parameters 208 used by the simulation system 200 can specify one or more states of one or more simulated object(s) within the simulated environment 204. For instance, as a simulated object moves within the simulated environment 204 during a simulation run, the simulation system 200 (e.g., a scenario recorder) can obtain state data indicative of one or more states of the simulated object at one or more times. The state(s) can be indicative of the position(s), heading(s), speed(s), etc. of the simulated object within the simulated environment at these one or more times. The simulation system 200 can trace and/or track these state(s) to determine a motion trajectory of the simulated object that corresponds to the motion of the simulated object within the simulated environment 200.

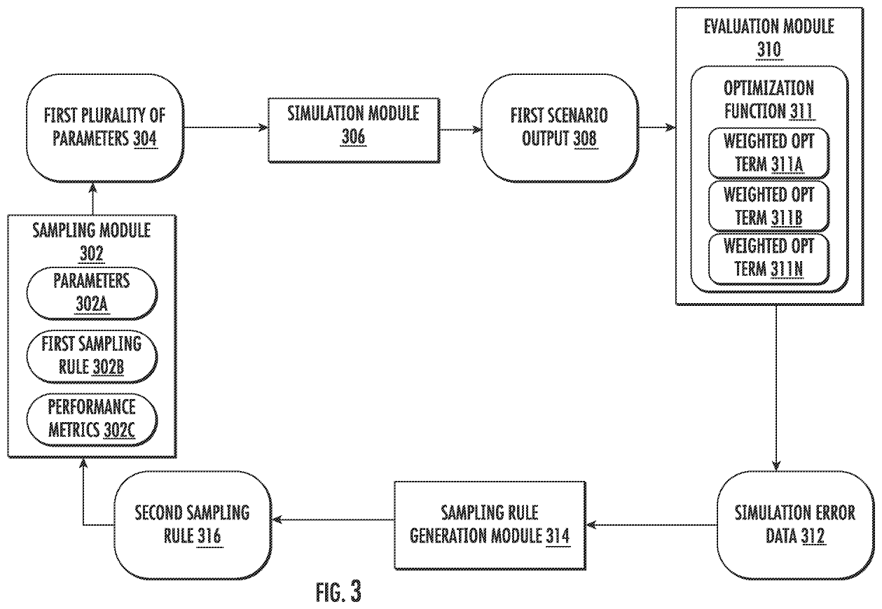

FIG. 3 depicts an example data flow diagram for determination of a second sampling rule using an optimization function according to example embodiments of the present disclosure. More particularly, a first plurality of testing parameters 304 can be obtained using sampling module 302 based at least in part on a first sampling rule 302B. The first plurality of testing parameters 304 can be associated with an autonomous vehicle testing scenario 302A. The autonomous vehicle testing scenario 302A can be or otherwise represent a scenario in which an autonomous vehicle can operate. As an example, the autonomous vehicle testing scenario 302A may represent a series of maneuvers that an autonomous vehicle must perform to navigate a specific series of roads. As another example, the autonomous vehicle testing scenario 302A may represent one or more maneuvers in response to action(s) taken by a separate testing entity(s) (e.g., additional vehicle(s), one or more pedestrian(s), a road obstruction, a traffic pattern, etc.). More generally, it should be noted that the autonomous vehicle testing scenario 302A can broadly represent any scenario that the autonomous vehicle could encounter.

The autonomous vehicle testing scenario 302A can include and/or correspond to a plurality of performance metrics 302C. A performance metric 302C can be or otherwise indicate a performance value and/or performance threshold necessary for compliance with a certain aspect of the autonomous vehicle testing scenario 302A. As an example, the performance metric 302C may indicate a performance threshold that an autonomous vehicle must achieve for a certain maneuver performed during the autonomous vehicle testing scenario 302A (e.g., entering an intersection, exiting a driveway, exiting a roundabout, etc.). If the performance value of an autonomous vehicle (e.g., a scalar value, a binary value, etc.) for a performance metric 302C does not meet the performance threshold, an error can be detected for that particular performance metric 302C. As another example, a performance threshold for perception of a non-compliant testing entity (e.g., a runaway shopping cart, etc.) may be or otherwise indicate a threshold amount of time to perceive the non-compliant testing entity. As such, the plurality of performance metrics 302C can be utilized to evaluate the performance of, and detect error(s) for, the autonomous vehicle for any perception, prediction, and/or motion planning operations completed during the autonomous vehicle testing scenario 302A.

The first plurality of testing parameters 304 can be or otherwise include parameters that specify operating condition(s) for the autonomous vehicle testing scenario 302A. Rather, the first plurality of testing parameters 304 can include any parameter associated with the testing of an autonomous vehicle testing scenario 302A. As an example, the parameters 304 may describe environmental condition(s) for the autonomous vehicle testing scenario 302A (e.g., humidity, sunlight, cloud coverage, weather, temperature, wind, etc.). As another example, the parameters 304 may describe vehicle maneuver(s) required to be performed for the autonomous vehicle testing scenario 302A (e.g., execution of a certain turn maneuver, acceleration, deceleration, reaction to external testing entity(s), motion planning, etc.). As another example, the parameters 304 may describe operational condition(s) for the autonomous vehicle testing scenario 302A (e.g., a speed limit, no-stopping zones, a number of lanes, object(s) included in a road network, lateral clearance, underbody clearance, turn radius, a degree of incline/decline, bike lanes, general road conditions (e.g., surface characteristics, types of lanes, laws of the road, etc.), etc.). As yet another example, the parameters 304 may describe a location, pose, type and/or behavior for each of one or testing entities included in the scenario 302A (e.g., specifying that a testing entity is riding a bicycle and is not compliant with road rules, etc.). For example, the parameters 304 may describe an actor located at the sidewalk of an intersection, and who's behavior includes facing the intersection and walking into the intersection at predetermined time. As such, the parameters 304 included in the first plurality of testing parameters can broadly describe any possible detail or characteristic of the autonomous vehicle testing scenario 302A.

The first plurality of testing parameters 304 can be obtained by the sampling module 302 based at least in part on a first sampling rule 302B. The first sampling rule 302B can describe or otherwise indicate a certain group of parameters to be sampled from (e.g., selected from, etc.). As an example, a group of parameters can exist for an autonomous vehicle testing scenario 302A. A sampling rule 302B can be configured to indicate a certain type of parameter (e.g., parameters 304) from the group of parameters that emphasizes one or more particular performance metrics for an autonomous vehicle testing scenario 302A. For example, a first sampling rule 302B can be configured to emphasize an “entering intersection” performance metric for an autonomous vehicle testing scenario 302A. To do so, the first sampling rule 302B can indicate a sampling of parameters 304 that are most likely to cause an error for the “entering intersection” performance metric (e.g., adding a number of actors to the intersection, decreasing compliance for actors in the intersection, adding pedestrian actors to the intersection, reducing visibility, increasing occlusion of the vehicle, increasing adverse weather conditions, etc.). Based on the first sampling rule 302B, the sampling module 302 can then select the first plurality of parameters 304. In such fashion, the sampling module 302 can utilize the sampling rule 302B to sample a first plurality of parameters 304 that are configured to emphasize a certain aspect of the autonomous vehicle testing scenario 302A.

It should be noted that the generation of a sampling rule (e.g., the first sampling rule 302B, etc.) can be accomplished in a variety of ways. As an example, a user (e.g., a testing engineer, etc.) can design an initial sampling rule that is not configured to emphasize any particular performance metric of the autonomous vehicle testing scenario (e.g., to identify any initial errors in the simulation, etc.). As another example, a computing system can utilize an optimization function (e.g., error loss characterization, etc.) to generate a sampling rule configured to emphasize parameter(s) most associated with a performance metric from a plurality of performance metrics. Additionally, or alternatively, the optimization function itself can be optimized by a user and/or the computing system to characterize the error loss of the simulation more accurately.

Once the first plurality of testing parameters 302A is obtained by the sampling module 302 based on the first sampling rule 302B , the autonomous vehicle testing scenario 302A can be simulated using the first plurality of testing parameters 304 using the simulation module 306 to obtain a first scenario output 308. It should be noted that the simulation of the autonomous vehicle testing scenario 304 can be accomplished using any type of simulation module(s) and/or system(s) (e.g., simulation module 306, etc.). The first scenario output 308 can describe an overall pass/fail state for the autonomous vehicle testing scenario 304. Additionally, in some implementations, the first scenario output 308 can include a plurality of performance values that respectively correspond to the plurality of performance metrics 302C. For example, the first scenario output 308 may include a value (e.g., a scalar value, etc.) indicative of the autonomous vehicle's performance in each of the plurality of performance metrics 302C. The pass/fail state described by the first scenario output 308 can be based at least in part on a number and/or degree of deviations from the ideal performance described by the plurality of performance metrics 302C. For example, it may be required that performance of the autonomous vehicle falls within the ideal range of only one or more of the plurality of performance metrics 302C to obtain a passing state. For another example, it may be required that performance of the autonomous vehicle falls within the ideal range of each performance metric 302C for a passing state.

Additionally, in some implementations, the first scenario output 308 can describe or otherwise indicate the actions performed by the autonomous vehicle during the simulation of the autonomous vehicle testing scenario 302A (e.g., any perception, prediction, motion, planned motion, etc.). As an example, the first scenario output 308 can include a time-stepped log of the perception, prediction, motion planning, and any other operations performed by the autonomous vehicle during the autonomous vehicle testing scenario 302A. As another example, the first scenario output 308 can describe any intermediary outputs and/or branching decisions of the autonomous vehicle during the simulation. For example, the first scenario output 308 may describe an intermediary perception output from a machine-learned model among a series of machine-learned models utilized in a perception system of the autonomous vehicle. In such fashion, the first scenario output 308 can be analyzed to determine sources of error within the operations performed by the autonomous vehicle and/or the internal intermediate functions that led to the operations.

An evaluation module 310 can evaluate an optimization function 311 to obtain simulation error data 312. The optimization function 311 itself can evaluate (and/or can be configured to evaluate) the first scenario output 308. More particularly, the optimization function (e.g., an error loss function, etc.) can evaluate the differences between the first scenario output 308 (e.g., a pass/fail state, performance values for the plurality of performance metrics, etc.) and ideal values and/or ranges of values for the plurality of performance metrics 302C to obtain the simulation error data 312. The first scenario output 308 can correspond to a performance metric of the plurality of performance metrics 302C. As an example, the first scenario output 308 may deviate from ideal values for a subset of the plurality of performance metrics 302C. The optimization function 311 (e.g., the derivative of an R2 function, an error loss function, a loss and/or optimization function comprising multiple weighted terms, etc.) can evaluate the first scenario output 308 to obtain the simulation error data 312. The simulation error data 312 can correspond to, or otherwise indicate, one performance metric of particular importance. Thus, in such fashion, the optimization function 311 can be utilized to obtain simulation error data 312, which can identify a performance metric of particular importance from the plurality of performance metrics 312C.

In some implementations, the optimization function 311 can include a plurality of weighted optimization terms 311A-311N. Each weighted optimization term (e.g., 311A, 311B, etc.) can be configured to evaluate a respective performance metric of the plurality of performance metrics 302C (e.g., characterize a respective error loss for each metric, etc.). As an example, the plurality of performance metrics 302C may include a performance metric for braking under icy road conditions. The optimization function 311 may include a weighted optimization term (e.g., 311A, 311B, etc.) that evaluates the performance metric that is weighted relatively lower than other optimization terms 311A-311N. Because the weighting of the optimization term is relatively low, the simulation error data 312 is relatively unlikely to correspond to the performance metric for braking under icy road conditions. Alternatively, in some implementations, the optimization function 311 may include a plurality of weighted optimization terms 311A-311N that can be respectively associated with a plurality of aspects of the autonomous vehicle testing scenario 302A. As an example, a weighted optimization term (e.g., 311A, 311B, etc.) of the plurality of weighted optimization terms 311A-311N may be configured to evaluate a subset of the plurality of performance metrics 302C that are associated with an environmental aspect of the autonomous vehicle testing scenario 302A. For example, the weighted optimization term (e.g., 311A, 311B, etc.) may evaluate a subset of parameters that are related to performing various maneuvers in icy road conditions.

Based on the simulation error data 312, a sampling rule generation module 314 can determine a second sampling rule 316 associated with the performance metric of the plurality of performance metrics 302C indicated by the simulation error data 312. As an example, the first scenario output 308 can indicate that the simulation of the autonomous vehicle testing scenario 302A failed. Additionally, the first scenario output 308 can identify errors (e.g., value(s) outside of an ideal, etc.) associated with a subset of the plurality of performance metrics 302C. However, many of these errors may be of less importance than others, or may share a causal relationship with other errors (e.g., an error in behavior for a first performance metric may then cause an error in behavior for a second performance metric, etc.). As such, it is particularly important to identify the most influential, or important, errors among the subset of performance metrics 302C. To do so, the optimization function 311 can be evaluated to obtain the simulation error data 312 that corresponds to the performance metric of particular importance from the subset of performance metrics 302C. Based on the optimization function 311, a second sampling rule 316 can be determined using the sampling rule generation module 314. The second sampling rule 316 can be configured to emphasize the identified performance metric. More particularly, the second sampling rule 316 can be configured to select parameters that will increase the error associated with the performance metric of the plurality of performance metrics 302C.

For example, if the first sampling rule 302B used to sample the first plurality of parameters 304 generated a minor error associated with the parameter (e.g., only slightly outside the range of ideal behavior, etc.), the second sampling rule 316 can be configured to generate a greater error. In such fashion, the optimization function 311 can be used to determine a second sampling rule 316 that narrows the “search space” among the plurality of performance metrics 302C, therefore facilitating identification of the source of the error associated with the performance metric.

A second plurality of testing parameters can be obtained for the autonomous vehicle according to the second sampling rule 316 using the sampling module 302. In some implementations, the second plurality of testing parameters can include fewer parameters than the first plurality of testing parameters 304. More particularly, by utilizing the optimization function 311 to narrow the testing parameter search space, the second sampling rule 316 can be more specifically focused on the source of error than the first sampling rule 302B, and can therefore eliminate a number of extraneous or irrelevant testing parameters when sampling for the second plurality of testing parameters.

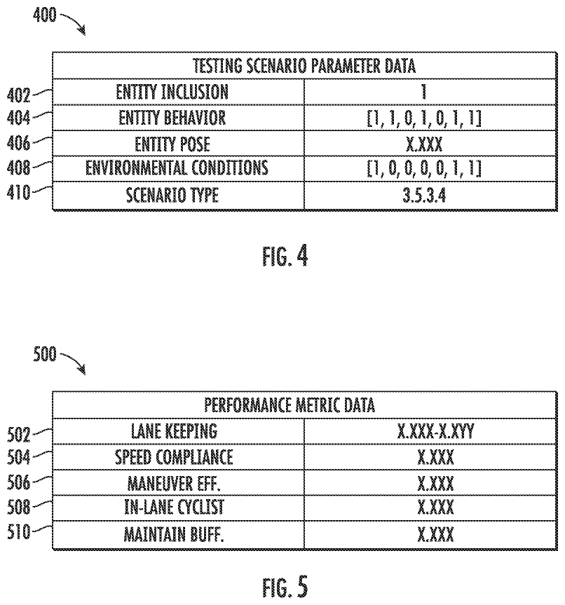

FIG. 4 depicts an example of testing scenario parameter data according to example embodiments of the present disclosure. The testing scenario parameter data can include a plurality of parameters 402-410. It should be noted that the parameters 402-410 are depicted merely to illustrate certain example aspect(s) of the present disclosure, and are not limiting with regards to the parameters that may be included in testing scenario parameter data 400. Rather, parameter data 400 may include any number or type of parameters. can include any parameter associated with the testing of an autonomous vehicle testing scenario. As an example, the testing scenario parameter data 400 may describe environmental condition(s) for the autonomous vehicle testing scenario (e.g., humidity, sunlight, cloud coverage, weather, temperature, wind, etc.). As another example, the testing scenario parameter data 400 may describe vehicle maneuver(s) required to be performed for the autonomous vehicle testing scenario (e.g., execution of a certain turn maneuver, acceleration, deceleration, reaction to external testing entity(s), motion planning, etc.). As another example, the testing scenario parameter data 400 may describe operational condition(s) for the autonomous vehicle testing scenario (e.g., a speed limit, no-stopping zones, a number of lanes, object(s) included in a road network, lateral clearance, underbody clearance, turn radius, a degree of incline/decline, bike lanes, general road conditions (e.g., surface characteristics, types of lanes, laws of the road, etc.), etc.). As yet another example, the testing scenario parameter data 400 may describe a location, pose, type and/or behavior for each of one or testing entities included in the scenario (e.g., specifying that a testing entity is riding a bicycle and is not compliant with road rules, etc.). For example, the testing scenario parameter data 400 may describe an actor located at the sidewalk of an intersection, and who's behavior includes facing the intersection and walking into the intersection at predetermined time. As such, the parameters included in the testing scenario parameter data 400 can broadly describe any possible detail or characteristic of the autonomous vehicle testing.

In some implementations, the testing scenario parameter data 400 may include an entity inclusion parameter 402. The entity inclusion parameter 402 may describe or otherwise control the inclusion of one or more certain testing entities within the simulation of a vehicle testing scenario. For example, the entity inclusion parameter may indicate that a pedestrian is included in a simulation of an autonomous vehicle testing scenario. Alternatively, or additionally, in some implementations, the entity inclusion parameter 402 may indicate whether a type or class of entity (e.g., pedestrians, vehicles, autonomous vehicles, non-compliant actors, etc.) is included in the simulation of the autonomous vehicle testing scenario.

In some implementations, the testing scenario parameter data 400 may include an entity behavior parameter 404. As depicted, the parameter can include data for a plurality of behavioral aspects for an entity. For example, the entity behavior parameter 404 may be or otherwise represent a vector of bits, each bit corresponding to a certain behavior (e.g., situational awareness, compliance, movement(s), etc.). Alternatively, in some implementations, the entity behavior parameter 404 can include one or objects and/or data structures descriptive of the behavior of one or more entities.

In some implementations, the testing scenario parameter data 400 may include an entity pose parameter 406. The entity pose parameter 406 can describe, control, or otherwise indicate the pose of a testing entity to be included in the simulation of the autonomous vehicle testing scenario. As an example, a pedestrian testing entity can be included in the simulation. The entity pose parameter 406 can describe a location for the entity (e.g., located at a crosswalk at an intersection, etc.), and can additionally describe an orientation of the entity (e.g., facing the north side of the intersection, etc.). In some implementations, the entity pose parameter 406 can describe a pose for a plurality of testing entities to be included in the testing scenario parameter data 400.

In some implementations, the testing scenario parameter data 400 may include an environmental conditions parameter 408. The environmental conditions parameter 408 can describe, indicate, or otherwise control each of the environmental conditions for the simulation of the autonomous vehicle testing scenario. As an example, the environmental conditions parameter 408 may describe one or more of the humidity, sunlight, cloud coverage, weather, temperature, and wind forces for the simulation of the autonomous vehicle testing scenario. It should be noted that the environmental conditions parameter 408 can be utilized to describe any aspect or degree of environmental condition in which the autonomous vehicle testing scenario may be simulated.

In some implementations, the testing scenario parameter data 400 may include a scenario type parameter 410. The scenario type parameter 410 may describe, indicate, or otherwise control the type of scenario for the autonomous vehicle testing scenario being simulated. More particularly, in some implementations, autonomous vehicle testing scenarios can be organized within scenario families based on certain shared characteristics or commonalities (e.g., required maneuver(s), required operation(s) (e.g., perception, prediction, etc.), shared environmental characteristic(s) (e.g., adverse weather conditions, night time, day time, etc.), shared performance metric(s) (e.g., perception in response to occlusion, etc.), etc.). As an example, scenarios may be grouped by a common required maneuver (e.g., entering an intersection, etc.). For example, a scenario family may include a first scenario in which a vehicle enters an intersection and performs a right turn maneuver, and a second scenario in which a vehicle enters an intersection and performs a left turn maneuver. As another example, a scenario family may be grouped based on a shared adverse weather condition. For example, a scenario family may include a first scenario in which a vehicle takes a right turn in icy road conditions, and a second scenario in which the vehicle takes a left turn against oncoming traffic in icy road conditions.

In some implementations, the scenario type parameter 410 can indicate a certain scenario type from within a scenario family. For example, the scenario family may be a scenario family grouped by a certain maneuver through an intersection. The scenario type parameter 410 may indicate a type of scenario from the family in which the intersection is densely populated, or may instead indicate a type of scenario from the family in which the intersection is sparsely populated.

Alternatively, in some implementations, the scenario type parameter 410 can indicate a certain scenario family from which to select a scenario. For example, the scenario families may be grouped by certain required maneuvers or other aspects. The scenario type parameter 410 may indicate a type of scenario family in which the autonomous vehicle navigates an intersection, or may instead indicate a scenario family in which the autonomous vehicle navigates a highway.

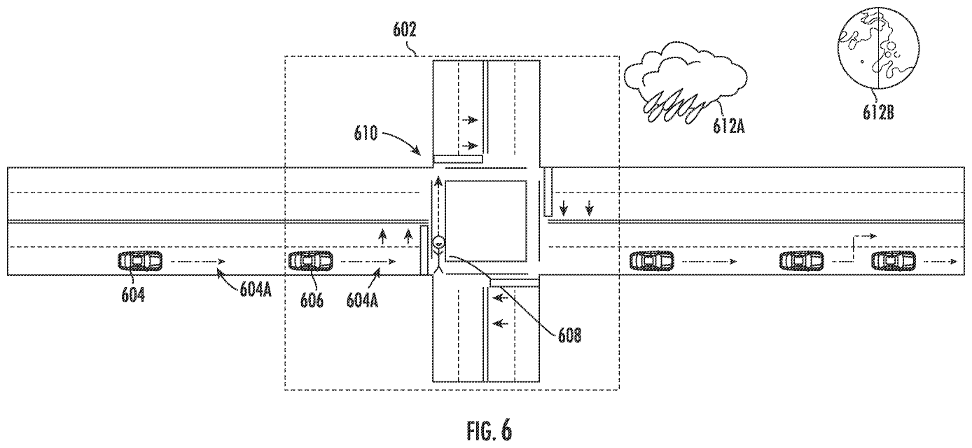

FIG. 5 depicts an example of performance metric data according to example embodiments of the present disclosure. The performance metric data 500 can include a plurality of performance metrics 502-510. It should be noted that the performance metrics 502-510 are depicted merely to illustrate certain example aspect(s) of the present disclosure, and are not limiting with regards to the type or number of performance metrics 502-510 that may be included in performance metric data 500. A performance metric (e.g., 502-510, etc.) can be or otherwise indicate a performance value and/or performance threshold necessary for compliance with a certain aspect of the autonomous vehicle testing scenario. As an example, a performance metric (e.g., 502-510, etc.) may indicate a performance threshold that an autonomous vehicle must achieve for a certain maneuver performed during the autonomous vehicle testing scenario (e.g., entering an intersection, exiting a driveway, exiting a roundabout, etc.). If the performance value of an autonomous vehicle (e.g., a scalar value, a binary value, etc.) for a performance metric does not meet the performance threshold, an error can be detected for that particular performance metric (e.g., 502-510, etc.). As another example, a performance threshold for perception of a non-compliant testing entity (e.g., a runaway shopping cart, etc.) may be or otherwise indicate a threshold amount of time to perceive the non-compliant testing entity. As such, the plurality of performance metrics 502-510 can be utilized to evaluate the performance of, and detect error(s) for, the autonomous vehicle for any perception, prediction, and/or motion planning operations completed during the autonomous vehicle testing scenario.

Additionally, or alternatively, in some implementations, each of the plurality of performance metrics 502-510 can describe an ideal performance value or a range of ideal performance for a particular aspect of the autonomous vehicle testing scenario. As an example, a performance metric (e.g., 502-510, etc.) can be or otherwise describe a value (e.g., a scalar value, a binary value, an integer value, etc.) or range of values associated with performance of a certain driving maneuver. The performance of the maneuver during the testing scenario can be evaluated (e.g., using an evaluation module, etc.) to obtain a value representative of how the vehicle performed the maneuver. The representative value and the ideal value (e.g., the performance metric) can be compared, and an error can be detected when performance of the vehicle deviates from the ideal performance by a certain degree. As an example, the performance metric (e.g., 502-510, etc.) can indicate a range of values from 5 ms to 10 ms that represent an ideal performance for perceiving a moving object. The representative value of performance of the perception operation by the autonomous vehicle can be 25 ms. An error can be detected based on the performance of the autonomous vehicle deviating from the ideal performance described by the performance metric by a certain degree.

In some implementations, the performance metric data 500 may include a lane keeping performance metric 502. The lane keeping performance metric 502 may indicate, quantify, or otherwise describe ideal behavior for an aspect of autonomous vehicle performance in the simulation of the autonomous vehicle testing scenario. As an example, the lane keeping metric 502 may indicate an ideal degree of movement within a lane over time. As another example, the lane keeping metric 502 may indicate a maximum number of times that the autonomous vehicle may deviate outside of the lane indicators.

In some implementations, the performance metric data 500 may include a speed compliance metric 504. The speed compliance metric 504 may indicate, quantify, or otherwise describe ideal behavior for an aspect of autonomous vehicle performance in the simulation of the autonomous vehicle testing scenario. As an example, the speed compliance metric 504 may indicate an ideal degree of speed variation within a certain range of time. As another example, the speed compliance metric 504 may indicate a maximum number of times that the speed of the autonomous vehicle may deviate from an ideal speed range.

In some implementations, the performance metric data 500 may include a maneuver efficiency metric 506. The maneuver efficiency metric 506 may indicate, quantify, or otherwise describe ideal behavior for an aspect of autonomous vehicle performance in the simulation of the autonomous vehicle testing scenario. As an example, the maneuver efficiency metric 506 may indicate an ideal efficiency for performance of a certain maneuver (e.g., a certain speed, distance traveled, energy expenditure, etc.). As another example, the maneuver efficiency metric 506 may indicate a certain maneuver to be selected by the autonomous vehicle when navigating a certain section of a road segment (e.g., indicating that a merge maneuver should be utilized at a certain time-point, etc.).

In some implementations, the performance metric data 500 may include an in-lane cyclist metric 508. The in-lane cyclist metric 508 may indicate, quantify, or otherwise describe ideal behavior for autonomous vehicle performance in the simulation of a specific aspect or challenge of the autonomous vehicle testing scenario. As an example, the in-lane cyclist metric 508 may indicate one or more types of permitted behavioral response to the inclusion of an in-lane cyclist (e.g., switch lanes, stop the car, slow the car, etc.). As another example, the in-lane cyclist metric 508 may indicate a degree of success or compliance for avoidance of the in-lane cyclist. As such, it should be broadly understood that a performance metric may indicate or describe an overall level of success in navigating a series of maneuvers or responding to certain phenomena (e.g., in-lane cyclist metric 508, etc.).

In some implementations, the performance metric data 500 may include a buffering distance metric 510. The buffering distance metric 510 may indicate, quantify, or otherwise describe ideal behavior for an aspect of autonomous vehicle performance in the simulation of the autonomous vehicle testing scenario. As an example, the buffering distance metric 510 may indicate an ideal distance to maintain from a vehicle in front of the autonomous vehicle (e.g., a certain speed, distance traveled, energy expenditure, etc.). As another example, the buffering distance metric 510 may indicate a maximum number of times the autonomous vehicle can fail to maintain a buffering distance behind a vehicle.

FIG. 6 depicts a data flow diagram for simulation of an autonomous vehicle testing scenario using a sampled plurality of testing parameters according to example embodiments of the present disclosure. More particularly, the vehicle testing scenario 602 can be or otherwise describe a specific scenario to be simulated and tested (e.g., testing of a right turn operation, etc.). Additionally, or alternatively, in some implementations, the scenario 602 can be a scenario of a certain scenario type. Vehicle testing parameters can be sampled according to a sampling rule (e.g., first sampling rule 302B of FIG. 3, etc.). The vehicle testing parameters can describe the conditions under which the scenario 602 takes place (e.g., number/pose/behavior of actor(s), environmental conditions, etc.). As depicted, the vehicle testing scenario 602 can depict a simulated scenario in which an autonomous vehicle 606 navigates an intersection 610. Vehicle testing parameters associated with the vehicle testing scenario 602 can specify one or more conditions in which the simulation of the vehicle testing scenario 602 takes place (e.g., rain conditions 612A, night-time conditions 612B, etc.).

As an example, the vehicle testing parameters (e.g., parameters of a vehicle testing tuple, etc.) can describe a location, pose, and behavior of a testing entity 608. As depicted, the testing entity 608 can be located in the southwest corner of the intersection 610, and can face the northwest corner of the intersection 610. Additionally, the parameters can describe a behavior of the testing entity 608 such that the testing entity 608 crosses the intersection 610 in a non-compliant manner (e.g., crossing when crosswalk signage indicates not to cross, etc.). The parameters can also specify a number of additional testing entities. For example, the parameters can specify a vehicle entity 604 located behind the vehicle 606. More particularly, the parameters can specify that the vehicle entity 604 is located behind the vehicle 606, and can describe a movement vector 604A for the vehicle entity 606 alongside any relevant behaviors for the vehicle entity 606.

In some implementations, parameters can be sampled based on a sampling rule (e.g., sampling rule 302B of FIG. 3, etc.) that emphasizes certain aspects of the scenario 602. For example, the scenario 602 may first be simulated such that the behavior of the pedestrian testing entity 608 is configured to walk across the intersection 610 in a manner compliant with road laws (e.g., crossing when permitted according to signage, etc.). Parameters for the scenario 602 may then be re-sampled to emphasize certain aspects of the scenario 602. For example, a second set of parameters could be sampled for the scenario 602 such that the behavior of the pedestrian testing entity 608 is configured to navigate the intersection 610 erratically in a manner that is non-compliant with road laws (e.g., quickly entering the intersection when not permitted according to signage, etc.). As such, various factors and/or aspects of the scenario 602 can be adjusted based on the sampling rule utilized to obtain parameters for simulation of the scenario 602.

The parameters (e.g., the first plurality of parameters 304 of FIG. 3, etc.) sampled according to the sampling strategy can specify any number of environmental conditions for the scenario 602. As an example, the parameters can specify rain conditions 612A. As another example, the parameters can specify a time of day and any associated lighting conditions (e.g., night-time conditions 612B, etc.). Additionally, the parameters can describe a certain quantity or level for each of the environmental conditions. For example, the parameters may specify a very heavy rainfall condition 612A. As such, the parameters can broadly describe any aspect or characteristic for the simulation of the vehicle testing scenario 602.

In some implementations, the vehicle testing scenario 602 can be or otherwise represent an unknown testing scenario 602. More particularly, data can be obtained that describes a scenario type for the scenario 602 that an autonomous vehicle (e.g., simulated vehicle 604, etc.) has not yet operated under and/or has not yet been designed to operate under (e.g., not included in an operational design domain, etc.). As an example, an unknown scenario type for scenario 602 can describe a specific form of non-compliant behavior for a pedestrian 608 (e.g., a testing entity, etc.) entering an intersection 610. For example, the scenario type for the scenario 602 may represent a scenario type in which the pedestrian 608 does leave the intersection 610 after entering (e.g., a particular type of non-compliance, etc.).

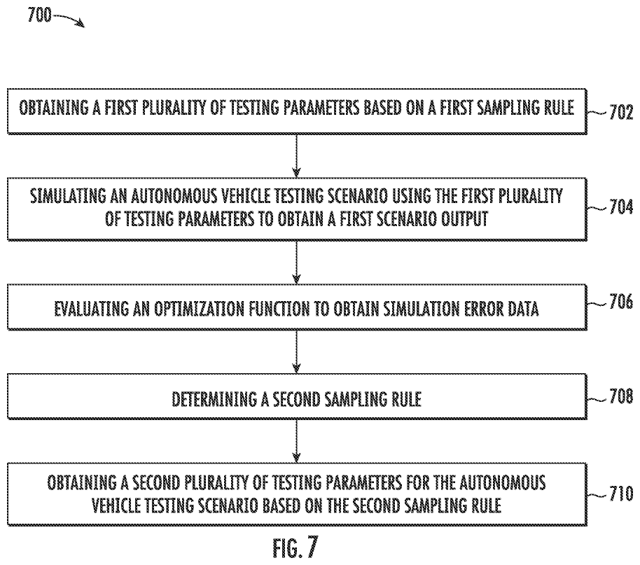

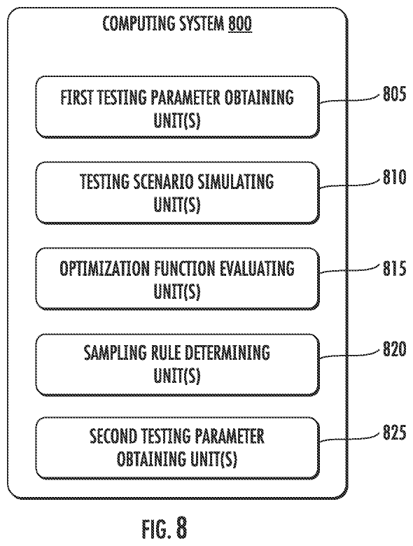

FIG. 7 depicts a flowchart of a method 700 for obtaining sampled parameters according to a sampling rule determined using an optimization function according to example embodiments of the present disclosure. One or more portion(s) of the method 700 can be implemented by one or more computing devices such as, for example, the computing devices described in FIGS. 1, 2, 7, and 8. Moreover, one or more portion(s) of the method 700 can be implemented as an algorithm on the hardware components of the device(s) described herein (e.g., as in 1, 2, 7, and 8) to, for example, obtain sampled parameters according to a sampling rule determined using an optimization function FIG. 7 depicts elements performed in a particular order for purposes of illustration and discussion. Those of ordinary skill in the art, using the disclosures provided herein, will understand that the elements of any of the methods discussed herein can be adapted, rearranged, expanded, omitted, combined, and/or modified in various ways without deviating from the scope of the present disclosure.

At (702), the method 700 can include obtaining a first plurality of testing parameters based on a first sampling rule. For instance, a computing system (e.g., service entity computing system 185) can obtain a first plurality of testing parameters for an autonomous vehicle testing scenario. An autonomous vehicle testing scenario can be or otherwise represent a scenario in which an autonomous vehicle can operate. As an example, the autonomous vehicle testing scenario may represent a series of maneuvers that an autonomous vehicle must perform to navigate a specific series of roads. As another example, the autonomous vehicle testing scenario may represent one or more maneuvers in response to action(s) taken by a separate testing entity(s) (e.g., additional vehicle(s), one or more pedestrian(s), a road obstruction, a traffic pattern, etc.). More generally, it should be noted that the autonomous vehicle testing scenario can broadly represent any scenario that the autonomous vehicle could encounter.

The autonomous vehicle testing scenario can include a plurality of performance metrics. A performance metric can be or otherwise indicate a performance value and/or performance threshold necessary for compliance with a certain aspect of the autonomous vehicle testing scenario. As an example, the performance metric may indicate a performance threshold that an autonomous vehicle must achieve for a certain maneuver performed during the autonomous vehicle testing scenario (e.g., entering an intersection, exiting a driveway, exiting a roundabout, etc.). If the performance value of an autonomous vehicle (e.g., a scalar value, a binary value, etc.) for a performance metric does not meet the performance threshold, an error can be detected for that particular performance metric. As another example, a performance threshold for perception of a non-compliant testing entity (e.g., a runaway shopping cart, etc.) may be or otherwise indicate a threshold amount of time to perceive the non-compliant testing entity. As such, the plurality of performance metrics can be utilized to evaluate the performance of, and detect error(s) for, the autonomous vehicle for any perception, prediction, and/or motion planning operations completed during the autonomous vehicle testing scenario.

Additionally, or alternatively, in some implementations, each of the plurality of performance metrics can describe an ideal performance value or a range of ideal performance for a particular aspect of the autonomous vehicle testing scenario. As an example, a performance metric can be or otherwise describe a value (e.g., a scalar value, a binary value, an integer value, etc.) or range of values associated with performance of a certain driving maneuver. The performance of the maneuver during the testing scenario can be evaluated (e.g., using an evaluation module, etc.) to obtain a value representative of how the vehicle performed the maneuver. The representative value and the ideal value (e.g., the performance metric) can be compared, and an error can be detected when performance of the vehicle deviates from the ideal performance by a certain degree. As an example, the performance metric can indicate a range of values from 5 ms to 10 ms that represent an ideal performance for perceiving a moving object. The representative value of performance of the perception operation by the autonomous vehicle can be 25 ms. An error can be detected based on the performance of the autonomous vehicle deviating from the ideal performance described by the performance metric by a certain degree. As another example, the performance metric can indicate a binary value that represents an ideal performance for completely stopping before entering an intersection (e.g., a binary value). The representative value of performance of the complete stop operation by the autonomous vehicle can be 1 (e.g., the vehicle did stop). As the vehicle did not deviate from the ideal performance described by the performance metric, an error would not be detected.

The first plurality of testing parameters can be or otherwise include parameters that specify operating condition(s) for the autonomous vehicle testing scenario. Rather, the first plurality of testing parameters can include any parameter associated with the testing of an autonomous vehicle testing scenario. As an example, the parameters may describe environmental condition(s) for the autonomous vehicle testing scenario (e.g., humidity, sunlight, cloud coverage, weather, temperature, wind, etc.). As another example, the parameters may describe vehicle maneuver(s) required to be performed for the autonomous vehicle testing scenario (e.g., execution of a certain turn maneuver, acceleration, deceleration, reaction to external testing entity(s), motion planning, etc.). As another example, the parameters may describe operational condition(s) for the autonomous vehicle testing scenario (e.g., a speed limit, no-stopping zones, a number of lanes, object(s) included in a road network, lateral clearance, underbody clearance, turn radius, a degree of incline/decline, bike lanes, general road conditions (e.g., surface characteristics, types of lanes, laws of the road, etc.), etc.). As yet another example, the parameters may describe a location, pose, type and/or behavior for each of one or testing entities included in the scenario (e.g., specifying that a testing entity is riding a bicycle and is not compliant with road rules, etc.). For example, the parameters may describe an actor located at the sidewalk of an intersection, and who's behavior includes facing the intersection and walking into the intersection at predetermined time. As such, the parameters included in the first plurality of testing parameters can broadly describe any possible detail or characteristic of the autonomous vehicle testing scenario.

In some implementations, the plurality of parameters can additionally modify or adjust the type of autonomous vehicle testing scenario selected. As an example, a first plurality of testing parameters for an autonomous vehicle testing scenario may describe a scenario in which a vehicle takes a right turn through an intersection. A second plurality of testing parameters for an autonomous vehicle may describe a scenario in which a vehicle navigates a roundabout turn. Additionally, or alternatively, in some implementations, the scenario type can be sampled from within a scenario family or from a separate scenario family.

More particularly, in some implementations, scenarios can be organized within scenario families based on certain shared characteristics or commonalities (e.g., required maneuver(s), required operation(s) (e.g., perception, prediction, etc.), shared environmental characteristic(s) (e.g., adverse weather conditions, night time, day time, etc.), shared performance metric(s) (e.g., perception in response to occlusion, etc.), etc.). As an example, scenarios may be grouped by a common required maneuver (e.g., entering an intersection, etc.). For example, a scenario family may include a first scenario in which a vehicle enters an intersection and performs a right turn maneuver, and a second scenario in which a vehicle enters an intersection and performs a left turn maneuver. As another example, a scenario family may be grouped based on a shared adverse weather condition. For example, a scenario family may include a first scenario in which a vehicle takes a right turn in icy road conditions, and a second scenario in which the vehicle takes a left turn against oncoming traffic in icy road conditions. As such, it should be broadly understood that a plurality of parameters can, in some implementations, describe the scenario itself, and that a sampling rule can additionally indicate whether a scenario should be sampled from within a scenario family or from a separate scenario family.

The first plurality of testing parameters can be obtained based at least in part on a first sampling rule. The first sampling rule can describe or otherwise indicate a certain group of parameters to be sampled from (e.g., selected from, etc.). As an example, a group of parameters can exist for an autonomous vehicle testing scenario. A sampling rule can be configured to indicate a certain type of parameter from the group of parameters that emphasizes one or more particular performance metrics for an autonomous vehicle testing scenario. For example, a first sampling rule can be configured to emphasize an “entering intersection” performance metric for an autonomous vehicle testing scenario. To do so, the first sampling rule can indicate a sampling of parameters that are most likely to cause an error for the “entering intersection” performance metric (e.g., adding a number of actors to the intersection, decreasing compliance for actors in the intersection, adding pedestrian actors to the intersection, reducing visibility, increasing occlusion of the vehicle, increasing adverse weather conditions, etc.). In such fashion, a sampling rule can be or otherwise describe a method of sampling parameters (e.g., for inclusion in the plurality of testing parameters, etc.) that is configured to emphasize a certain aspect of an autonomous vehicle testing scenario.

It should be noted that the generation of a sampling rule (e.g., the first sampling rule, etc.) can be accomplished in a variety of ways. As an example, a user (e.g., a testing engineer, etc.) can design an initial sampling rule that is not configured to emphasize any particular performance metric of the autonomous vehicle testing scenario (e.g., to identify any initial errors in the simulation, etc.). As another example, a computing system can utilize an optimization function (e.g., error loss characterization, etc.) to generate a sampling rule configured to emphasize parameter(s) most associated with a performance metric from a plurality of performance metrics. Additionally, or alternatively, the optimization function itself can be optimized by a user and/or the computing system to characterize the error loss of the simulation more accurately.

At (704), the method 700 can include simulating an autonomous vehicle testing scenario using the first plurality of testing parameters to obtain a first scenario output. For instance, a computing system (e.g., service entity computing system 185) can simulate the autonomous vehicle testing scenario using the first plurality of testing parameters to obtain a first scenario output. It should be noted that the simulation of the autonomous vehicle testing scenario can be accomplished using any type of simulation system(s). The first scenario output can describe an overall pass/fail state for the autonomous vehicle testing scenario. Additionally, in some implementations, the first scenario output can include a plurality of performance values that respectively correspond to the plurality of performance metrics. For example, the first scenario output may include a value (e.g., a scalar value, etc.) indicative of the autonomous vehicle's performance in each of the plurality of performance metrics. The pass/fail state can be based at least in part on a number and/or degree of deviations from the ideal performance described by the plurality of performance metrics. For example, it may be required that performance of the autonomous vehicle falls within the ideal range of only one or more of the plurality of performance metrics to obtain a passing state. For another example, it may be required that performance of the autonomous vehicle falls within the ideal range of each performance metric for a passing state.

Additionally, in some implementations, the first scenario output can describe or otherwise indicate the actions performed by the autonomous vehicle during the simulation of the autonomous vehicle testing scenario (e.g., any perception, prediction, motion, planned motion, etc.). As an example, the first scenario output can include a time-stepped log of the perception, prediction, motion planning, and any other operations performed by the autonomous vehicle during the autonomous vehicle testing scenario. As another example, the first scenario output can describe any intermediary outputs and/or branching decisions of the autonomous vehicle during the simulation. For example, the first scenario output may describe an intermediary perception output from a machine-learned model among a series of machine-learned models utilized in a perception system of the autonomous vehicle. In such fashion, the first scenario output can be analyzed to determine sources of error within the operations performed by the autonomous vehicle and/or the internal intermediate functions that led to the operations.

At (706), the method 700 can include evaluating an optimization function to obtain simulation error data. For instance, a computing system (e.g., service entity computing system 185) can evaluate an optimization function that evaluates the first scenario output to obtain simulation error data. More particularly, the optimization function (e.g., an error loss function, etc.) can evaluate the differences between the first scenario output (e.g., a pass/fail state, performance values for the plurality of performance metrics, etc.) and ideal values and/or ranges of values for the plurality of performance metrics to obtain the simulation error data. The first scenario output can correspond to a performance metric of the plurality of performance metrics. As an example, the first scenario output may deviate from ideal values for a subset of the plurality of performance metrics. The optimization function (e.g., the derivative of an R2 function, an error loss function, a loss and/or optimization function comprising multiple weighted terms, etc.) can evaluate the first scenario output to obtain the simulation error data. The simulation error data can correspond to, or otherwise indicate, one performance metric of particular importance. Thus, in such fashion, the optimization function can be utilized to obtain simulation error data, which can identify a performance metric of particular importance from the plurality of performance metrics.

At (708), the method 700 can include determining a second sampling rule. For instance, a computing system (e.g., service entity computing system 185) can determine a second sampling rule associated with the performance metric based on the optimization function. As an example, the first scenario output can indicate that the simulation of the autonomous vehicle testing scenario failed. Additionally, the first scenario output can identify errors (e.g., value(s) outside of an ideal, etc.) associated with a subset of the plurality of performance metrics. However, many of these errors may be of less importance than others, or may share a causal relationship with other errors (e.g., an error in behavior for a first performance metric may then cause an error in behavior for a second performance metric, etc.). As such, it is particularly important to identify the most influential, or important, errors among the subset of performance metrics. To do so, the optimization function can be evaluated to obtain the simulation error data that corresponds to the performance metric of particular importance from the subset of performance metrics. Based on the optimization function, a second sampling rule can be determined that is configured to emphasize the identified performance metric. More particularly, the second sampling rule can be configured to select parameters that will increase the error associated with the performance metric. For example, if the first sampling rule generated a minor error associated with the parameter (e.g., only slightly outside the range of ideal behavior, etc.), the second sampling rule can be configured to generate a greater error. In such fashion, the optimization function can be used to determine a second sampling rule that narrows the “search space” among the plurality of performance metrics, therefore facilitating identification of the source of the error associated with the performance metric.

At (710), the method 700 can include obtaining a second plurality of testing parameters for the autonomous vehicle testing scenario based on the second sampling rule. For instance, a computing system (e.g., service entity computing system 185) can obtain a second plurality of testing parameters for the autonomous vehicle according to the second sampling rule. In some implementations, the second plurality of testing parameters can include fewer parameters than the first plurality of testing parameters. More particularly, by utilizing the optimization function to narrow the testing parameter search space, the second sampling rule can be more specifically focused on the source of error than the first sampling rule, and can therefore eliminate a number of extraneous or irrelevant testing parameters when sampling for the second plurality of testing parameters.

In some implementations, obtaining the second plurality of testing parameters can include determining a plurality of testing parameters using the second sampling rule. The plurality of testing parameters can be associated with the performance metric of the plurality of performance metrics. As an example, the first plurality of testing parameters may include a large number of actors, each with their own behavior parameters. The simulation error data can correspond to or otherwise identify a performance metric for braking under icy road conditions. The second sampling rule can indicate a rule to ignore actor parameters (e.g., eliminating actors from the simulation, etc.), and instead focus on the plurality of testing parameters that may emphasize the performance metric for braking under icy road conditions (e.g., sampling additional weather parameters, sampling a brake failure or inefficiency parameter, etc.). After identifying the plurality of testing parameters associated with the performance metric, at least a subset of testing parameters from the plurality of testing parameters can be obtained.

In some implementations, the optimization function can include a plurality of weighted optimization terms. Each weighted optimization term can be configured to evaluate a respective performance metric of the plurality of performance metrics (e.g., characterize a respective error loss for each metric, etc.). As an example, the plurality of performance metrics may include a performance metric for braking under icy road conditions. The optimization function may include a weighted optimization term that evaluates the performance metric that is weighted relatively lower than other optimization terms. Because the weighting of the optimization term is relatively low, the simulation error data is relatively unlikely to correspond to the performance metric for braking under icy road conditions. Alternatively, in some implementations, the optimization function may include a plurality of weighted optimization terms that can be respectively associated with a plurality of aspects of the autonomous vehicle testing scenario. As an example, a weighted optimization term of the plurality of weighted optimization terms may be configured to evaluate a subset of the plurality of performance metrics that are associated with an environmental aspect of the autonomous vehicle testing scenario. For example, the weighted optimization term may evaluate a subset of parameters that are related to performing various maneuvers in icy road conditions.

In some implementations, the autonomous vehicle testing scenario can be simulated using the second plurality of testing parameters to obtain a second scenario output. The simulation and obtaining of the second scenario output can be performed using a method identical or substantially similar to those for simulation and obtaining of the first scenario output. In some implementations, the simulation error data can be descriptive of an error value, and the optimization function can be used to evaluate the second scenario output to obtain second simulation error data that is descriptive of a second error value. As an example, the first error value may be descriptive of behavior that is 15% outside a value or range indicative of ideal behavior for the performance metric. The second error value may be descriptive of behavior that is different than the simulation error data (e.g., 45% outside a value or range, 5% outside a value or range, etc.). As such, a change between the first error value and the second error value can indicate that the second sampling rule has affected the performance of the autonomous vehicle for the performance metric.

In some implementations, the second error value can be less than the first error value. To follow the previously described example, the first error value may be descriptive of behavior that is 15% outside a value or range indicative of ideal behavior for the performance metric. The second error value may be descriptive of behavior that only 3% outside a value or range indicative of ideal behavior for the performance metric. If the second error value is less than the first error value, the optimization function can be adjusted to adjust (e.g., increase, decrease, etc.) a weighting of one or more weighted optimization terms of the optimization function. More particularly, if the second sampling rule does not select a plurality of parameters that increase the second error value, it may indicate that the simulation error data incorrectly corresponds or identifies the performance metric, and therefore that one or more weighted optimization terms are improperly weighted. In response, the one or more weighted optimization terms can be adjusted. Once adjusted, the optimization function can be re-evaluated to obtain simulation error data that corresponds to a second performance metric different from the first performance metric.

In some implementations, the second error value can be greater than the first error value. To follow the previously described example, the first error value may be descriptive of behavior that is 15% outside a value or range indicative of ideal behavior for the performance metric. The second error value may be descriptive of behavior that 45% outside a value or range indicative of ideal behavior for the performance metric. If the second error value is greater than the first error value, a third sampling rule can be determined based at least in part on the optimization function and/or the simulation error data. The third sampling rule can be configured to emphasize a second performance metric of the plurality of performance metrics, or can be configured to further emphasize the first performance metric. In such fashion, sampling rules can be iteratively determined until a source of error is found for the performance metric.

In some implementations, the computing system can be or otherwise include a service entity computing system associated with a service entity that facilitates autonomous vehicle implementation. As an example, the service entity can facilitate provision of both first-party and third-party autonomous vehicle implementations (e.g., systems and methods that provide autonomous functionality for autonomous vehicles, etc.). Additionally, in some implementations, the service entity computing system may be updated with parameters obtained based on a sampling rule. As an example, the second plurality of testing parameters can be obtained for the autonomous vehicle testing scenario based on the second sampling rule. One or more components of the service entity computing system (e.g., a vehicle testing system, a vehicle testing knowledge structure, etc.) can be updated with the second plurality of testing parameters. In such fashion, parameters obtained using the second sampling rate can be stored and utilized to facilitate further testing and validation of autonomous vehicle implementations of the service entity.

In some implementations, the computing system and vehicle testing knowledge structure can be or otherwise include a service entity computing system associated with a service entity that facilitates autonomous vehicle services. As an example, the service entity can facilitate provision of both first-party and third-party autonomous vehicle services (e.g., delivery services, transportation services, courier services, aerial transportation services, etc.). Additionally, in some implementations, the autonomous vehicle can be associated with the service entity (e.g., a first-party autonomous vehicle of the service entity, a third-party autonomous vehicle of a vehicle provider that provides services facilitated by the service entity, etc.). Alternatively, in some implementations, the computing system can be or otherwise include an autonomous vehicle computing system of the autonomous vehicle that is configured to implement various autonomous vehicle systems (e.g., motion planning system(s), perception system(s), prediction system(s), etc.).

Various means can be configured to perform the methods and processes described herein. FIG. 8 depicts example units associated with a computing system for performing operations and functions according to example embodiments of the present disclosure. As depicted, FIG. 8 depicts a computing system 800 that can include, but is not limited to, first testing parameter obtaining unit(s) 805; testing scenario simulating unit(s) 810; optimization function evaluating unit(s) 815; sampling rule determining unit(s) 820; and second testing parameter obtaining unit(s) 825.

In some implementations, one or more of the units may be implemented separately. In some implementations, one or more units may be a part of or included in one or more other units. These means can include processor(s), microprocessor(s), graphics processing unit(s), logic circuit(s), dedicated circuit(s), application-specific integrated circuit(s), programmable array logic, field-programmable gate array(s), controller(s), microcontroller(s), and/or other suitable hardware. The means can also, or alternately, include software control means implemented with a processor or logic circuitry, for example. The means can include or otherwise be able to access memory such as, for example, one or more non-transitory computer-readable storage media, such as random-access memory, read-only memory, electrically erasable programmable read-only memory, erasable programmable read-only memory, flash/other memory device(s), data registrar(s), database(s), and/or other suitable hardware. The means can be programmed to perform one or more algorithm(s) for carrying out the operations and functions described herein (including the claims).

The means can be programmed to perform one or more algorithm(s) for carrying out the operations and functions described herein. For instance, the means can be configured to obtain a first plurality of testing parameters for an autonomous vehicle testing scenario (e.g., obtained according to a first sampling rule, etc.). A first testing parameter obtaining unit 805 is an example of means for obtaining a first plurality of testing parameters for an autonomous vehicle testing scenario as described herein.

The means can be configured to simulate an autonomous vehicle testing scenario using a plurality of testing parameters to obtain a first scenario output. For example, the means can be configured to simulate, using the first plurality of testing parameters, the autonomous vehicle testing scenario (e.g., to obtain simulation error data that corresponds to a performance metric of the autonomous vehicle testing scenario, etc.). A testing scenario simulating unit 810 is one example of a means for simulating an autonomous vehicle testing scenario using a plurality of testing parameters as described herein.

The means can be configured to evaluate an optimization function. For example, the means can be configured to evaluate an optimization function that evaluates a first scenario output to obtain simulation error data. The simulation error data can correspond to a performance metric of an autonomous vehicle testing scenario (e.g., a breaking performance metric, etc.). An optimization function evaluating unit 815 is one example of a means for evaluating an optimization function as described herein.

The means can be configured to determine a sampling rule. For example, the means can be configured to determine a second sampling rule associated with a performance metric based at least in part on an optimization function (e.g., a sampling rule configured to emphasize the performance metric, etc.). A sampling rule determining unit 820 is one example of a means for determining a second sampling rule as described herein.

The means can be configured to obtain a second plurality of testing parameters. For example, the means can be configured to obtain a second plurality of testing parameters for an autonomous vehicle testing scenario based at least in part on a second sampling rule (e.g., selecting parameters for the second plurality of testing parameters according to the second sampling rule, etc.). A second testing parameter obtaining unit 825 is one example of a means for obtaining a second plurality of testing parameters as described herein.

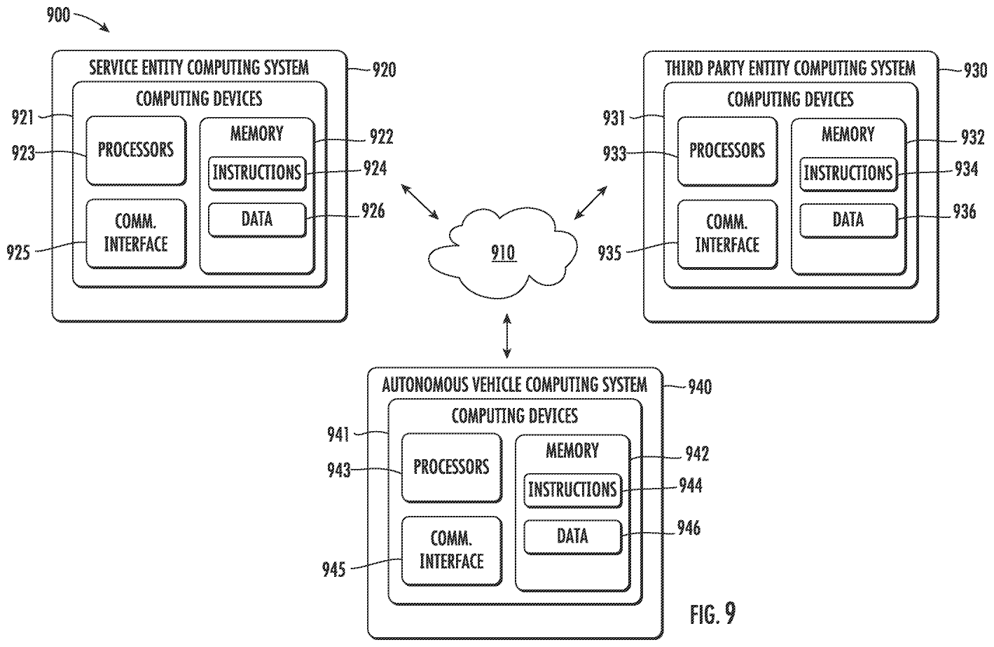

FIG. 9 depicts an example system 900 according to example aspects of the present disclosure. The example system 900 illustrated in FIG. 9 is provided as an example only. The components, systems, connections, and/or other aspects illustrated in FIG. 9 are optional and are provided as examples of what is possible, but not required, to implement the present disclosure. The example system 900 can include a service entity computing system 920 (e.g., that is associated with a service entity). The service entity computing system 920 can represent/correspond to the service entity computing systems 190A and 210 described herein. The example system 900 can include a third-party entity computing system 930 (e.g., that is associated with a third-party entity). The third-party entity computing system 930 can represent/correspond to the third-party entity computing systems 190B and 250 described herein. The example system 900 can include an autonomous vehicle computing system 940 (e.g., that is onboard an autonomous vehicle). The autonomous vehicle computing system 940 can represent/correspond to the autonomous vehicle computing system 110 described herein. The service entity computing system 920, the third-party entity computing system 930, and the autonomous vehicle computing system 940 can be communicatively coupled to one another over one or more communication network(s) 910. The networks 910 can correspond to any of the networks described herein, such as communication network 120.

The computing device(s) 921 of the service entity computing system 920 can include processor(s) 923 and a memory 922. The one or more processors 923 can be any suitable processing device (e.g., a processor core, a microprocessor, an ASIC, a FPGA, a controller, a microcontroller, etc.) and can be one processor or a plurality of processors that are operatively connected. The memory 922 can include one or more non-transitory computer-readable storage media, such as RAM, ROM, EEPROM, EPROM, one or more memory devices, flash memory devices, data registrar, etc., and combinations thereof.

The memory 922 can store information that can be accessed by the one or more processors 923. For example, the memory 922 (e.g., one or more non-transitory computer-readable storage mediums, memory devices) can include computer-readable instructions 924 that can be executed by the one or more processors 923. The instructions 924 can be software written in any suitable programming language or can be implemented in hardware. Additionally, or alternatively, the instructions 924 can be executed in logically and/or virtually separate threads on processor(s) 923.

For example, the memory 922 can store instructions 924 that when executed by the one or more processors 923 cause the one or more processors 923 (the service entity computing system 920) to perform operations such as any of the operations and functions of the service entity computing system (or for which it is configured), one or more of the operations and functions for communicating between a third-party entity and/or a service entity and/or an autonomous vehicle, one or more portions of method 700, and/or one or more of the other operations and functions of the computing systems described herein.

The memory 922 can store data 926 that can be obtained (e.g., acquired, received, retrieved, accessed, created, stored, etc.). The data 926 can include, for example, data associated with communications (e.g., messages, calls, callbacks, etc.), data associated with software package(s) (e.g., Cloud SDK data), data associated with one or more backends, data associated with an API platform, batched data, data associated with vehicle simulation, data associated with autonomous vehicle testing scenario(s), data associated with performance metrics, data associated with outputs of autonomous vehicle testing scenario simulation, data associated with optimization function(s), data associated with sampling of parameters, data associated with sampling rule(s), data associated with optimization function evaluation, data associated with autonomous vehicles, data associated with autonomous vehicles, data associated with third-party entities, sensor data, map data, vehicle state data, vehicle location data, perception data, prediction data, motion planning data, data associated with a vehicle client, data associated with a communication network, data associated with an API, data associated with a library, data associated with user interfaces, data associated with user input, and/or other data/information such as, for example, that described herein. In some implementations, the computing device(s) 921 can obtain data from one or more memories that are remote from the service entity computing system 920.

The computing device(s) 921 can also include a communication interface 925 used to communicate with one or more other system(s) on-board an autonomous vehicle and/or remote from the service entity computing system, such as third-party entity computing system 930 and an autonomous vehicle computing system 940. The communication interface 925 can include any circuits, components, software, etc. for communicating via one or more networks (e.g., network(s) 910). The communication interface 925 can include, for example, one or more of a communications controller, receiver, transceiver, transmitter, port, conductors, software and/or hardware for communicating data.

The third-party entity computing system 930 can include one or more computing device(s) 931 that are remote from the service entity computing system 920 and/or the autonomous vehicle computing system 940. The computing device(s) 931 can include one or more processors 933 and a memory 932. The one or more processors 933 can be any suitable processing device (e.g., a processor core, a microprocessor, an ASIC, a FPGA, a controller, a microcontroller, etc.) and can be one processor or a plurality of processors that are operatively connected. The memory 932 can include one or more tangible, non-transitory computer-readable storage media, such as RAM, ROM, EEPROM, EPROM, one or more memory devices, flash memory devices, data registrar, etc., and combinations thereof.

The memory 932 can store information that can be accessed by the one or more processors 933. For example, the memory 932 (e.g., one or more tangible, non-transitory computer-readable storage media, one or more memory devices, etc.) can include computer-readable instructions 934 that can be executed by the one or more processors 933. The instructions 934 can be software written in any suitable programming language or can be implemented in hardware. Additionally, or alternatively, the instructions 934 can be executed in logically and/or virtually separate threads on processor(s) 933.

For example, the memory 932 can store instructions 934 that when executed by the one or more processors 933 cause the one or more processors 933 to perform operations such as any of the operations and functions of the third-party entity computing system (or for which it is configured), one or more of the operations and functions for communicating between a third-party entity and/or a service entity and/or an autonomous vehicle, one or more portions of method 700, and/or one or more of the other operations and functions of the computing systems described herein.

The memory 932 can store data 936 that can be obtained. The data 936 can include, for example, data associated with communications (e.g., messages, calls, callbacks, etc.), data associated with software package(s) (e.g., Cloud SDK data), data associated with one or more backends, data associated with vehicle simulation, data associated with autonomous vehicle testing scenario(s), data associated with performance metrics, data associated with outputs of autonomous vehicle testing scenario simulation, data associated with optimization function(s), data associated with sampling of parameters, data associated with sampling rule(s), data associated with optimization function evaluation, data associated with autonomous vehicles, data associated with third-party entities, data of an associated vehicle fleet, sensor data, map data, vehicle state data, vehicle location data, perception data, prediction data, motion planning data, data associated with a vehicle client, data associated with a communication network, data associated with an API, data associated with a library, data associated with user interfaces, data associated with user input, and/or other data/information such as, for example, that described herein.

The computing device(s) 931 can also include a communication interface 935 used to communicate with one or more system(s) onboard an autonomous vehicle and/or another computing device that is remote from the system 930, such as autonomous vehicle computing system 940 and service entity computing system 920. The communication interface 935 can include any circuits, components, software, etc. for communicating via one or more networks (e.g., network(s) 910). The communication interface 935 can include, for example, one or more of a communications controller, receiver, transceiver, transmitter, port, conductors, software and/or hardware for communicating data.

The autonomous vehicle computing system 940 can include one or more computing device(s) 941 that are remote from the service entity computing system 920 and the third-party entity computing system 930. The computing device(s) 941 can include one or more processors 943 and a memory 942. The one or more processors 943 can be any suitable processing device (e.g., a processor core, a microprocessor, an ASIC, a FPGA, a controller, a microcontroller, etc.) and can be one processor or a plurality of processors that are operatively connected. The memory 942 can include one or more tangible, non-transitory computer-readable storage media, such as RAM, ROM, EEPROM, EPROM, one or more memory devices, flash memory devices, data registrar, etc., and combinations thereof.

The memory 942 can store information that can be accessed by the one or more processors 943. For example, the memory 942 (e.g., one or more tangible, non-transitory computer-readable storage media, one or more memory devices, etc.) can include computer-readable instructions 944 that can be executed by the one or more processors 943. The instructions 944 can be software written in any suitable programming language or can be implemented in hardware. Additionally, or alternatively, the instructions 944 can be executed in logically and/or virtually separate threads on processor(s) 943.

For example, the memory 942 can store instructions 944 that when executed by the one or more processors 943 cause the one or more processors 943 to perform operations such as any of the operations and functions of the autonomous vehicle computing system (or for which it is configured), one or more of the operations and functions for communicating between a third-party entity and/or a service entity and/or an autonomous vehicle, one or more portions of method 700, and/or one or more of the other operations and functions of the computing systems described herein.

The memory 942 can store data 946 that can be obtained. The data 946 can include, for example, data associated with communications (e.g., messages, calls, callbacks, etc.), data associated with software package(s) (e.g., Cloud SDK data), data associated with one or more backends, batched data, data associated with vehicle simulation, data associated with autonomous vehicle testing scenario(s), data associated with performance metrics, data associated with outputs of autonomous vehicle testing scenario simulation, data associated with optimization function(s), data associated with sampling of parameters, data associated with sampling rule(s), data associated with optimization function evaluation, data associated with third-party entities, sensor data, map data, vehicle state data, vehicle location data, perception data, prediction data, motion planning data, data associated with a vehicle client, data associated with a telecommunication network, data associated with one or more API(s), data associated with a library, data associated with user interfaces, data associated with user input, and/or other data/information such as, for example, that described herein.

The computing device(s) 941 can also include a communication interface 945 used to communicate with one or more system(s) onboard a vehicle and/or another computing device that is remote from the system 940, such as third-party entity computing system 930 and/or service entity computing system 920. The communication interface 945 can include any circuits, components, software, etc. for communicating via one or more networks (e.g., network(s) 910). The communication interface 945 can include, for example, one or more of a communications controller, receiver, transceiver, transmitter, port, conductors, software and/or hardware for communicating data.

The network(s) 910 can be any type of network or combination of networks that allows for communication between devices. In some implementations, the network(s) 910 can include one or more of a local area network, wide area network, the Internet, secure network, cellular network, mesh network, peer-to-peer communication link and/or some combination thereof and can include any number of wired or wireless links. Communication over the network(s) 910 can be accomplished, for example, via a communication interface using any type of protocol, protection scheme, encoding, format, packaging, etc.

Computing tasks discussed herein as being performed at computing device(s) remote from the vehicle can instead be performed at the vehicle (e.g., via the vehicle computing system), or vice versa. Such configurations can be implemented without deviating from the scope of the present disclosure. The use of computer-based systems allows for a great variety of possible configurations, combinations, and divisions of tasks and functionality between and among components. Computer-implemented operations can be performed on a single component or across multiple components. Computer-implemented tasks and/or operations can be performed sequentially or in parallel. Data and instructions can be stored in a single memory device or across multiple memory devices.

While the present subject matter has been described in detail with respect to specific example embodiments and methods thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A computer-implemented method, comprising:
obtaining, by a computing system comprising one or more computing devices, a first plurality of testing parameters for an autonomous vehicle testing scenario based at least in part on a first sampling rule, wherein the autonomous vehicle testing scenario is associated with a plurality of performance metrics;
simulating, by the computing system, the autonomous vehicle testing scenario using the first plurality of testing parameters to obtain a first scenario output;
evaluating, by the computing system, an optimization function that evaluates the first scenario output to obtain simulation error data that corresponds to a performance metric of the plurality of performance metrics;
determining, by the computing system based at least in part on the simulation error data, a second sampling rule associated with the performance metric; and
obtaining, by the computing system, a second plurality of testing parameters for the autonomous vehicle testing scenario based at least in part on the second sampling rule.

2. The computer-implemented method of claim 1, wherein the optimization function is configured to characterize an error loss for at least one of the plurality of performance metrics.

3. The computer-implemented method of claim 1, wherein the method further comprises updating, by the computing system, an autonomous vehicle testing system with the second plurality of testing parameters.

4. The computer-implemented method of claim 1, wherein obtaining, by the computing system, the second plurality of testing parameters for the autonomous vehicle testing scenario comprises:
determining, by the computing system using the second sampling rule, a plurality of testing parameters associated with the performance metric of the plurality of performance metrics; and
obtaining, by the computing system, at least a subset of the second plurality of testing parameters from the plurality of testing parameters associated with the performance metric of the plurality of performance metrics.

5. The computer-implemented method of claim 1, wherein the method further comprises simulating, by the computing system, the autonomous vehicle testing scenario using the second plurality of testing parameters to obtain a second scenario output.

6. The computer-implemented method of claim 5, wherein:
the simulation error data is descriptive of an error value;
the method further comprises evaluating, by the computing system, the optimization function to obtain second simulation error data that corresponds to the performance metric of the vehicle testing scenario, wherein the second simulation error data is descriptive of a second error value.

7. The computer-implemented method of claim 6, wherein the optimization function comprises a plurality of weighted optimization terms, each weighted optimization term configured to evaluate a respective performance metric of the plurality of performance metrics of the autonomous vehicle testing scenario.

8. The computer-implemented method of claim 7, wherein:
the second error value is less than the first error value; and
the method further comprises adjusting, by the computing system, the optimization function to adjust a weighting of one or more weighted optimization terms associated with the performance metric of the autonomous vehicle testing scenario.

9. The computer-implemented method of claim 6, wherein:
the second error value is greater than the first error value; and
the method further comprises determining, by the computing system based at least in part on the second simulation error data, a third sampling rule configured to emphasize a second performance metric of the plurality of performance metrics.

10. The computer-implemented method of claim 1, wherein:
the first scenario output is descriptive of one or more autonomous vehicle driving maneuvers; and
the ground truth label is respectively descriptive of one or more optimal autonomous vehicle driving maneuvers.

11. The computer-implemented method of claim 1, wherein one or more of the first plurality of testing parameters are associated with at least one of:
one or more environmental conditions for the testing scenario;
a pose for each of one or more testing entities for the testing scenario;
a testing entity type for each of the one or more testing entities for the testing scenario;
one or more road conditions for the testing scenario; or
one or more behaviors for each entity included in the testing scenario.

12. A computing system comprising:
one or more processors;
one or more tangible, non-transitory computer readable media storing computer-readable instructions that when executed by the one or more processors cause the one or more processors to perform operations, the operations comprising:
obtaining a first plurality of testing parameters for an autonomous vehicle testing scenario based at least in part on a first sampling rule, wherein the autonomous vehicle testing scenario is associated with plurality of performance metrics;
simulating the autonomous vehicle testing scenario using the first plurality of testing parameters to obtain a first scenario output;
evaluating an optimization function that evaluates a difference between the first scenario output and a ground truth label to obtain simulation error data that corresponds to a performance metric of the plurality of performance metrics;
determining, based at least in part on the simulation error data, a second sampling rule associated with the performance metric; and
obtaining a second plurality of testing parameters for the autonomous vehicle testing scenario based at least in part on the second sampling rule.

13. The computing system of claim 12, wherein the operations further comprise updating an autonomous vehicle testing component of the computing system with the second plurality of testing parameters.

14. The computing system of claim 12, wherein obtaining the second plurality of testing parameters for the autonomous vehicle testing scenario comprises:
determining, using the second sampling rule, a plurality of testing parameters associated with the performance metric of the plurality of performance metrics; and
obtaining at least a subset of the second plurality of testing parameters from the plurality of testing parameters associated with the performance metric of the plurality of performance metrics.

15. The computing system of claim 12, wherein the operations further comprise simulating the autonomous vehicle testing scenario using the second plurality of testing parameters to obtain a second scenario output.

16. The computing system of claim 15, wherein:
the simulation error data is descriptive of an error value; and
the operations further comprise evaluating the optimization function to obtain second simulation error data that corresponds to the performance metric of the vehicle testing scenario, wherein the second simulation error data is descriptive of a second error value.

17. The computing system of claim 16, wherein the optimization function comprises a plurality of weighted optimization terms, each weighted optimization term configured to evaluate a respective performance metric of the plurality of performance metrics of the autonomous vehicle testing scenario.

18. The computing system of claim 17, wherein:
the second error value is less than the first error value; and
the operations further comprise adjusting the optimization function to adjust a weighting of one or more weighted optimization terms associated with the performance metric of the autonomous vehicle testing scenario.

19. One or more tangible, non-transitory computer readable media storing computer-readable instructions that when executed by one or more processors cause the one or more processors to perform operations, the operations comprising:
obtaining a first plurality of testing parameters for an autonomous vehicle testing scenario based at least in part on a first sampling rule, wherein the autonomous vehicle testing scenario comprises a plurality of performance metrics, wherein the first sampling rule is associated with a first performance metric;
simulating the autonomous vehicle testing scenario using the first plurality of testing parameters to obtain a first scenario output;
evaluating an optimization function that evaluates a difference between the first scenario output and a ground truth label to obtain simulation error data that corresponds to the first performance metric;
determining, based at least in part on the simulation error data, a second sampling rule associated with a second performance metric of the plurality of performance metrics; and
obtaining a second plurality of testing parameters for the autonomous vehicle testing scenario based at least in part on the second sampling rule.

20. The one or more tangible, non-transitory media of claim 19, wherein:
the simulation error data is descriptive of a simulation error value associated with the first performance metric, wherein the simulation error value is below a simulation error threshold;
the optimization function comprises a plurality of weighted optimization terms, each weighted optimization term configured to evaluate a respective performance metric of the plurality of performance metrics of the autonomous vehicle testing scenario; and
the operations further comprise at least one of:
adjusting a weighted optimization term of the plurality of weighted optimization terms that is associated with the first performance metric to reduce a weight of the weighted optimization term; or
adjusting a weighted optimization term of the plurality of weighted optimization terms that is associated with the second performance metric to increase a weight of the weighted optimization term.
